(19) United States
(12) Patent Application Publication
(10) Pub. No.: US 2026/0026198 A1
(43) Pub. Date: Jan. 22, 2026

(54) DISPLAY DEVICE, METHOD OF FABRICATING THE SAME, AND ELECTRONIC DEVICE INCLUDING DISPLAY DEVICE

(71) Applicant: Samsung Display Co., LTD., Yongin-si (KR)

(72) Inventors: Ji Seong YANG, Yongin-si (KR); Woo Man JI, Yongin-si (KR); Kyu Min KIM, Yongin-si (KR); Rae Young KIM, Yongin-si (KR); Soo Dong KIM, Yongin-si (KR); Sung Hoon LIM, Yongin-si (KR); Sun Kyu JOO, Yongin-si (KR)

(21) Appl. No.: 19/010,445

(22) Filed: Jan. 6, 2025

(30) Foreign Application Priority Data
Jul. 16, 2024 (KR) 10-2024-0093954

(51) Int. Cl. H10K 59/122

(52) U.S. Cl. CPC H10K 59/122

(57) ABSTRACT

A display device includes a substrate, an insulating layer disposed on the substrate, and including a trench in a portion thereof adjacent to an emission area without overlapping the emission area in a plan view, a first electrode disposed on the insulating layer, and overlapping the emission area and partially overlapping the trench in the plan view, an emission layer disposed on the first electrode, and overlapping the trench in the plan view, and a second electrode disposed on the emission layer, and overlapping the trench in the plan view, and disconnected by the trench.

The application claims priority to Korean Patent Application No. 10-2024-0093954, filed on Jul. 16, 2024, and all the benefits accruing therefrom under 35 U.S.C. § 119, the content of which in its entirety is herein incorporated by reference.

### BACKGROUND

### (1) Field of Invention

Various embodiments of the disclosure relate to a display device. Particularly, various embodiments of the disclosure relate to a display device, a method of fabricating the display device, and an electronic device including the display device.

### (2) Description of Related Art

With the development of information technology, the importance of a display device that is a connection medium between a user and information has been emphasized. Accordingly, various kinds of display devices, such as a liquid crystal display device and an organic light emitting display device, are widely used in various fields.

### SUMMARY

Various embodiments of the disclosure are directed to a display device with improved light output efficiency.

Various embodiments of the disclosure are directed to a method of fabricating the display device.

An embodiment of the disclosure provides a display device including: a substrate; an insulating layer disposed on the substrate, and including a trench adjacent in a portion thereof adjacent to an emission area without overlapping the emission area in a plan view; a first electrode disposed on the insulating layer, and overlapping the emission area and partially overlapping the trench in the plan view; an emission layer disposed on the first electrode, and overlapping the trench in the plan view; and a second electrode disposed on the emission layer, and overlapping the trench in the plan view, and disconnected by the trench.

In an embodiment, the trench may have a closed-loop shape in the plan view.

In an embodiment, a portion of the second electrode disposed inside the closed-loop shape of the trench may be electrically disconnected from a portion of the second electrode disposed outside the closed-loop shape of the trench.

In an embodiment, the display device may further include a first pixel defining layer disposed between the insulating layer and the first electrode without overlapping the emission area in the plan view.

In an embodiment, the first pixel defining layer may be disposed inside the closed-loop shape of the trench without overlapping the trench in the plan view.

In an embodiment, a portion of the trench may be defined between the first pixel defining layer and the emission area in the plan view.

In an embodiment, the first pixel defining layer may partially overlap an edge of the first electrode. In such an embodiment, a portion of the first electrode which overlaps the first pixel defining layer in the plan view may be disposed on a side surface of the first pixel defining layer, and have an incline corresponding to an incline of a side surface of the first pixel defining layer.

In an embodiment, the display device may further include a second pixel defining layer disposed between the first electrode and the emission layer, and overlapping the first pixel defining layer in the plan view, and covering an edge of the first electrode.

In an embodiment, an angle formed between an upper surface of the insulating layer and an inclined surface of the insulating layer that defines the trench may be in range from 0° to about 130°.

In an embodiment, the display device may further include a color filter layer disposed on the second electrode, and including a transmitting area overlapping the emission area in the plan view and a light blocking area enclosing the transmitting area in the plan view.

In an embodiment, the trench may overlap only the light blocking area without overlapping the transmitting area in the plan view.

In an embodiment, the display device may further include a color conversion layer disposed on the second electrode, and including a color conversion pattern overlapping the emission area in the plan view and a bank layer enclosing the color conversion pattern in the plan view.

In an embodiment, a surface area of the color conversion pattern may be greater than a surface area of the emission area.

In an embodiment, the bank layer may include a metal layer disposed on a side surface thereof which contacts the color conversion pattern.

An embodiment of the disclosure provides a display device including: a substrate; an insulating layer disposed on the substrate, and including trenches respectively defined between emission areas adjacent to each other in a first direction; pixel defining layers disposed on the insulating layer, and respectively disposed inside the trenches without overlapping the emission areas in a plan view; first electrodes disposed on the insulating layer and the pixel defining layers, and respectively overlapping the emission areas, and respectively partially overlapping the trenches in the plan view; an emission layer disposed on the first electrodes, and overlapping entire portions of the emission areas; in the plan view and a second electrode disposed on the emission layer, and overlapping the emission areas in the plan view, and disconnected by the trenches between the emission areas.

In an embodiment, each of the trenches may have a closed-loop shape in the plan view. In such an embodiment, the pixel defining layers may be respectively disposed inside the closed-loop shapes of the trenches.

In an embodiment, the trenches, the emission areas, and the pixel defining layers may overlap each other in the first direction.

In an embodiment, a width of each of the first electrodes in the first direction may be greater than a width of each of the emission areas in the first direction. In such an embodiment, a portion of each of the first electrodes, which does not overlap the emission area in the plan view, may overlap the trenches and the pixel defining layers in the plan view.

In an embodiment, a sum of lengths of sides of each of the emission areas which are adjacent to the trenches may be greater than a sum of lengths of sides which are not adjacent to the trenches.

An embodiment of the disclosure provides a method of fabricating a display device including: forming an insulating layer on a substrate; forming a trench in the insulating layer at a portion thereof adjacent to an emission area; forming a first electrode overlapping the emission area and at least a portion of the trench in a plan view on the insulating layer; forming an emission layer overlapping the trench in the plan view on the first electrode; and forming a second electrode overlapping an entire portion of the trench in the plan view on the emission layer. In such an embodiment, the second electrode is disconnected by the trench.

In an embodiment, the trench may be formed in a closed-loop shape in the plan view using a halftone mask.

In an embodiment, the method may further include, before forming the first electrode, forming a pixel defining layer inside the closed-loop shape of the trench without overlapping the trench in the plan view.

An electronic device includes a processor to provide input image data; and a display device to display an image based on the input image data, wherein the display device includes: a substrate; an insulating layer disposed on the substrate, and including a trench defined in a portion thereof adjacent to an emission area without overlapping the emission area in a plan view; a first electrode disposed on the insulating layer, and overlapping the emission area and partially overlapping the trench in the plan view; an emission layer disposed on the first electrode, and overlapping the trench in the plan view; and a second electrode disposed on the emission layer, and overlapping the trench in the plan view, and disconnected by the trench.

Details of various embodiments are included in the detailed descriptions and drawings.

### BRIEF DESCRIPTION OF THE DRAWINGS

FIG. 1 is a block diagram illustrating an embodiment of a display device.

FIG. 2 is a block diagram illustrating an embodiment of one of sub-pixels of FIG. 1.

FIG. 3 is a plan view illustrating an embodiment of a display panel of FIG. 1.

FIG. 4 is a sectional view illustrating an embodiment of the display panel of FIG. 3.

FIG. 5 is a sectional view illustrating another embodiment of the display panel of FIG. 3.

FIG. 6 is a plan view illustrating an embodiment of one of pixels of FIG. 3.

FIG. 7 is a sectional view taken along line I-I′ of FIG. 6.

FIG. 8 is an enlarged sectional view illustrating area A of FIG. 7.

FIG. 9 is a sectional view taken along line II-II′ of FIG. 6.

FIG. 10 is a sectional view illustrating another embodiment of FIG. 7.

FIG. 11 is a plan view illustrating another embodiment of one of the pixels of FIG. 3.

FIG. 12 is a plan view illustrating another embodiment of one of the pixels of FIG. 3.

FIGS. 13 to 20 are diagrams illustrating a method of fabricating a display device in accordance with an embodiment of the disclosure.

FIG. 21 is a block diagram of an electronic device according to an embodiment. Referring to FIG. 1, the electronic device 10 may include a display module 11, a processor 12, a memory 13, and a power module 14.

FIG. 22 shows schematic views of various embodiments of an electronic device.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

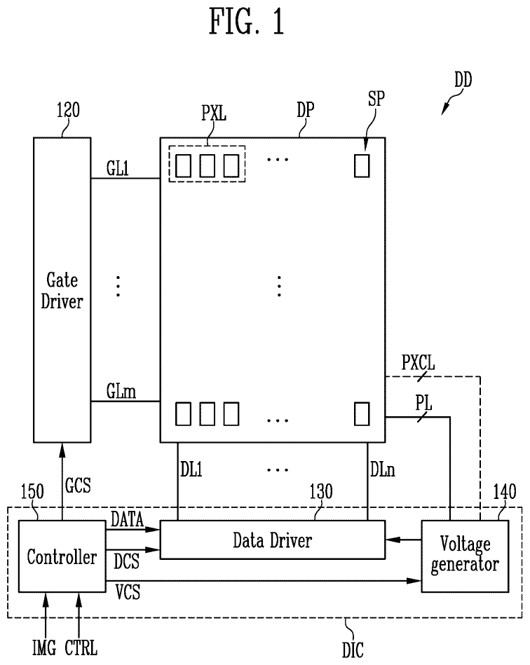

FIG. 1 is a block diagram illustrating an embodiment of a display device DD.

Referring to FIG. 1, an embodiment of the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn. Here, m and n are natural numbers greater than 1.

The sub-pixels SP may generate light in two or more colors. In an embodiment, for example, each of the sub-pixels SP may generate light in a color such as red, green, blue, cyan, magenta, or yellow.

Two or more sub-pixels among the sub-pixels SP may form (constitute or collectively define) one pixel PXL. In an embodiment, for example, the pixel PXL may include three sub-pixels, as illustrated in FIG. 1. As such, the pixel PXL may emit light of various colors and various luminances depending on the combination of light emitted from the sub-pixels included therein.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal instructing each frame to start, a horizontal synchronization signal, or the like.

The gate driver 120 may be disposed on one side of the display panel DP. However, embodiments are not limited to the aforementioned example. In an embodiment, for example, the gate driver 120 may be divided into two or more drivers that are physically and/or logically distinguished from each other. The drivers may be disposed on a first side of the display panel DP and a second side of the display panel DP opposite to the first side. As such, the gate driver 120 may be disposed around the display panel DP in various forms depending on the embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In an embodiment, the data control signal DCS may include a source start signal, a source shift clock, a source output enable signal, or the like.

The data driver 130 may receive voltages from the voltage generator 140. The data driver 130 may apply, using received voltages, data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLn. Hence, the sub-pixels SP may generate light corresponding to the data signals, and the display panel DP may display an image.

In an embodiment, the gate driver 120 and the data driver 130 may include complementary metal-oxide semiconductor (CMOS) circuit elements.

The voltage generator 140 may operate in response to a voltage control signal VCS provided from the controller 150. The voltage generator 140 is configured to generate a plurality of voltages and provide the generated voltages to components of the display device DD such as the gate driver 120, the data driver 130, and the controller 150. The voltage generator 140 may receive an input voltage from an external device of the display device DD and generate a plurality of voltages by regulating the received voltage.

The voltage generator 140 may generate a first power voltage and a second power voltage. The generated first and second power voltages may be provided to the sub-pixels SP through power lines PL. In an embodiment, at least one selected from the first and second power voltages may be provided from an external device to the display device DD.

In addition, the voltage generator 140 may provide various voltages and/or signals. In an embodiment, for example, the voltage generator 140 may provide one or more initialization voltages to be applied to the sub-pixels SP. In an embodiment, for example, during a sensing operation for sensing electrical characteristics of transistors and/or light emitting elements of the sub-pixels SP, a certain reference voltage may be applied to each of the first to n-th data lines DL1 to DLn. The voltage generator 140 may generate the reference voltage and transmit the reference voltage to the data driver 130. In an embodiment, for example, during a display operation for displaying an image on the display panel DP, common pixel control signals may be applied to the sub-pixels SP, and the voltage generator 140 may generate the pixel control signals. In an embodiment, the voltage generator 140 may provide pixel control signals to the sub-pixels SP through pixel control lines PXCL. Although FIG. 1 illustrates an embodiment where the pixel control lines PXCL are connected between the voltage generator 140 and the display panel DP, the embodiments are not limited thereto. In another embodiment, for example, the pixel control lines PXCL may be connected between the gate driver 120 and the display panel DP. In such an embodiment, the pixel control signals may be transmitted from the voltage generator 140 to the pixel control lines PXCL through the gate driver 120.

The controller 150 may control overall operations of the display device DD. The controller 150 may receive input image data IMG and a control signal CTRL corresponding thereto from an external device. The controller 150 may provide a gate control signal GCS, a data control signal DCS, and a voltage control signal VCS, in response to the control signal CTRL.

The controller 150 may convert the input image data IMG to be suitable for the display device DD or the display panel DP and then output image data DATA. In an embodiment, the controller 150 may align the input image data IMG to be suitable for the sub-pixels SP on a row-by-row basis and then output the image data DATA.

Two or more components of the data driver 130, the voltage generator 140, and the controller 150 may be mounted on a single integrated circuit. In an embodiment, as illustrated in FIG. 1, the data driver 130, the voltage generator 140, and the controller 150 may be included in a driver integrated circuit DIC. In such an embodiment, the data driver 130, the voltage generator 140, and the controller 150 may be components that are functionally separated from each other in the single driver integrated circuit DIC. In another embodiment, at least one selected from the data driver 130, the voltage generator 140, and the controller 150 may be provided as a component separated from the driver integrated circuit DIC.

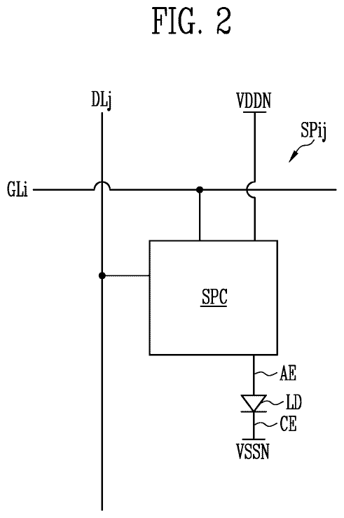

FIG. 2 is a block diagram illustrating an embodiment of one of the sub-pixels SP of FIG. 1. In FIG. 2, a sub-pixel SPij is illustrated, disposed on an i-th row (where i is an integer equal to or greater than 1 and less than or equal to m) and a j-th column (where j is an integer equal to or greater than 1 and less than or equal to n) among the sub-pixels SP of FIG. 1.

Referring to FIG. 2, in an embodiment, the sub-pixel SPij may include a sub-pixel circuit SPC and a light emitting element LD.

The light emitting element LD is connected between a first power voltage node VDDN and a second power voltage node VSSN. The first power voltage node VDDN may be connected to one of the power lines PL of FIG. 1 to receive a first power voltage. The second power voltage node VSSN may be connected to another one of the power lines PL of FIG. 1 to receive a second power voltage. The first power voltage may have a voltage level higher than the second power voltage.

The light emitting element LD may be connected between an anode electrode AE and a cathode electrode CE. The anode electrode AE may be connected to the first power voltage node VDDN through the sub-pixel circuit SPC. In an embodiment, for example, the anode electrode AE may be connected to the first power voltage node VDDN through one or more transistors included in the sub-pixel circuit SPC. The cathode electrode CE may be connected to the second power voltage node VSSN. The light emitting element LD is configured to emit light based on current flowing from the anode electrode AE to the cathode electrode CE.

The sub-pixel circuit SPC may be connected both to an i-gate line GLi among the first to m-th gate lines GL1 to GLm of FIG. 1 and to a j-th data line DLj among the first to n-th data lines DL1 to DLn of FIG. 1. In response to a gate signal received through the i-th gate line GLi, the sub-pixel circuit SPC may control the light emitting element LD to emit light based on a data signal received through the j-th data line DLj. In an embodiment, the sub-pixel circuit SPC may be further connected to the pixel control lines PXCL of FIG. 1. In such an embodiment, the sub-pixel circuit SPC may further control the light emitting element LD in response to pixel control signals received through the pixel control lines PXCL.

In an embodiment, the sub-pixel circuit SPC may include circuit elements, for example, transistors and one or more capacitors to perform aforementioned operations.

The transistors of the sub-pixel circuit SPC may include P-type transistors and/or N-type transistors. In an embodiment, the transistors of the sub-pixel circuit SPC may include a metal oxide silicon field effect transistor (MOSFET). In an embodiment, the transistors of the sub-pixel circuit SPC may include an amorphous silicon semiconductor, a monocrystalline silicon semiconductor, a polycrystalline silicon semiconductor, an oxide semiconductor, or the like.

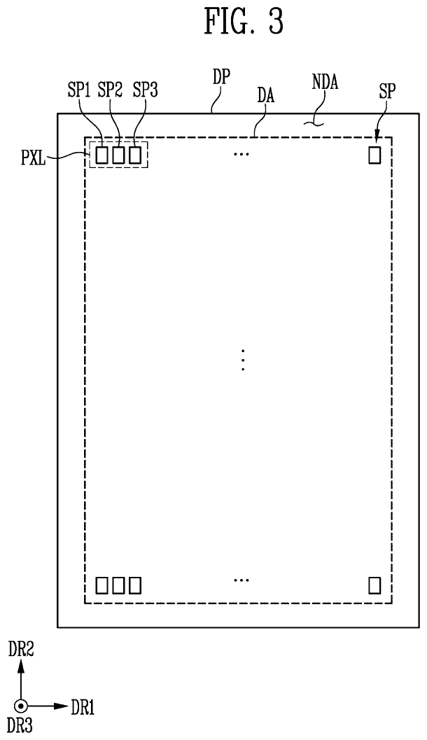

FIG. 3 is a plan view illustrating an embodiment of the display panel DP of FIG. 1.

Referring to FIG. 3, the display panel DP may include a display area DA and a non-display area NDA. The display panel DP may display an image through the display area DA. The non-display area NDA may be disposed around the display area DA.

The display panel DP includes sub-pixels SP in the display area DA. The sub-pixels SP may be arranged in a first direction DR1 and a second direction DR2 intersecting with the first direction DR1. Here, a third direction DR3 may be a direction perpendicular to the first direction DR1 and the second direction DR2, or a thickness direction of the display panel DP. In an embodiment, for example, the sub-pixels SP may be arranged in the form of a matrix in the first direction DR1 and the second direction DR2. In another embodiment, for example, the sub-pixels SP may be arranged in a zigzag form in the first direction DR1 and the second direction DR2. The arrangement of the sub-pixels SP may be changed depending on embodiments. The first direction DR1 may refer to a row direction, and the second direction DR2 may refer to a column direction.

Two or more sub-pixels among the sub-pixels SP may form one pixel PXL. Although FIG. 3 illustrates an embodiment where the pixel PXL includes three sub-pixels SP1 to SP3, the embodiments are not limited thereto. In another embodiment, for example, the pixel PXL may include two sub-pixels. Hereinafter, for convenience of explanation, it is assumed that the pixel PXL includes first to third sub-pixels SP1 to SP3.

Each of the first to third sub-pixels SP1 to SP3 may generate light of one among various colors such as red, green, blue, cyan, magenta, and yellow. Hereinafter, for convenience of description, embodiments where the first sub-pixel SP1 is configured to generate light in red, the second color pixel SP2 is configured to generate light in green, and the third sub-pixel SP3 is configured to generate light in blue will be mainly described, but not being limited thereto.

Each of the first to third sub-pixels SP1 to SP3 may include at least one light emitting element configured to generate light. In an embodiment, the light emitting elements of the first to third sub-pixels SP1 to SP3 may generate light in the same color. In an embodiment, for example, the light emitting elements of the first to third sub-pixels SP1 to SP3 may generate light in blue. In an embodiment, the light emitting elements of the first to third sub-pixels SP1 to SP3 may generate light in different colors. In an embodiment, for example, the light emitting elements of the first to third sub-pixels SP1 to SP3 may respectively generate light in red, green, and blue.

As a display panel DP, a self-emissive display panel such as an LED display panel using a micro-scale or nano-scale light emitting diode as a light emitting element, and an organic light emitting display panel (OLED panel) using an organic light emitting diode as a light emitting element may be used.

Components for controlling the sub-pixels SP may be disposed in the non-display area NDA. Lines connected to the sub-pixels SP, for example, the first to m-th gate lines GL1 to GLm, the first to n-th data lines DL1 to DLn, the power lines PL, and the pixel control lines PXCL of FIG. 1, may be disposed in the non-display area NDA.

At least one selected from the gate driver 120, the data driver 130, the voltage generator 140, and the controller 150 of FIG. 1 may be disposed in the non-display area NDA of the display panel DP. In an embodiment, the gate driver 120 may be disposed in the non-display area NDA. In such an embodiment, the data driver 130, the voltage generator 140, and the controller 150 may be implemented as the driver integrated circuit DIC of FIG. 1 that is separated from the display panel DP. The driver integrated circuit DIC may be connected to the lines disposed in the non-display area NDA. In an embodiment, the gate driver 120 along with the data driver 130, the voltage generator 140, and the controller 150 may be implemented as a single integrated circuit that is separate from the display panel DP.

In an embodiment, the display area DA may have various shapes. The display area DA may have a closed-loop shape, including linear and/or curved sides. In an embodiment, for example, the display area DA may have shapes such as a polygon, a circle, a semicircle, and an ellipse.

In an embodiment, the display panel DP may have a planar display surface. In an embodiment, the display panel DP may have a display surface that is at least partially rounded. In an embodiment, the display panel DP may be bendable, foldable, or rollable. In such embodiments, the display panel DP and/or a substrate of the display panel DP may include materials having flexible properties.

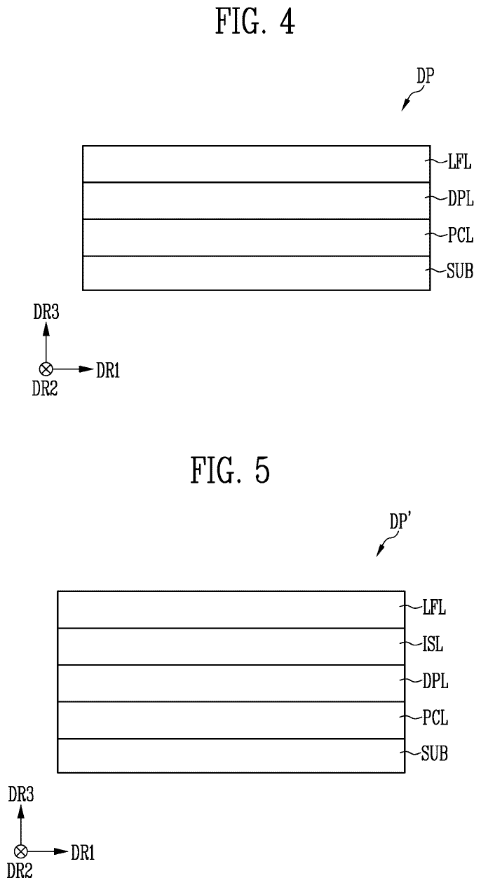

FIG. 4 is a sectional view illustrating an embodiment of the display panel of FIG. 3.

Referring to FIG. 4, an embodiment of a display panel DP may include a substrate SUB, and a pixel circuit layer PCL, a display element layer DPL, and a light functional layer LFL that are sequentially stacked on the substrate SUB in the third direction DR3 or the thickness direction of the display panel DP or the substrate SUB.

The substrate SUB may include or be made of insulating material such as glass or resin. In an embodiment, for example, the substrate SUB may include a glass substrate. In another embodiment, for example, the substrate SUB may include a polyimide (PI) substrate. In another embodiment, for example, the substrate SUB may include a silicon wafer substrate formed through a semiconductor process.

In an embodiment, the substrate SUB may include or be made of material having flexibility to be bendable or foldable, and may have a single-layer structure or a multilayer structure. In an embodiment, for example, the material having flexibility may include at least one selected from the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the embodiments are not limited to the aforementioned example.

The pixel circuit layer PCL may be disposed on the substrate SUB. The pixel circuit layer PCL may include insulating layers, and semiconductor patterns and conductive patterns disposed between the insulating layers. The conductive patterns of the pixel circuit layer PCL may function as circuit elements, lines, or the like.

The circuit elements of the pixel circuit layer PCL may include the respective sub-pixel circuits SPC (refer to FIG. 2) of the sub-pixels SP of FIG. 3. In other words, the circuit elements of the pixel circuit layer PCL may define transistors and one or more capacitors of the sub-pixel circuit SPC.

The lines of the pixel circuit layer PCL may include lines connected to the sub-pixels SP. The lines of the pixel circuit layer PCL may include various signal lines and/or voltage lines used to drive the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or scattering particles. In an embodiment, for example, the color conversion particles may include quantum dots. The quantum dots may convert the wavelength (or color) of light emitted from the display element layer DPL. The light functional layer LFL may further include light scattering patterns having scattering particles. In an embodiment, the light conversion patterns and the light scattering patterns may be omitted.

The light functional layer LFL may further include a color filter layer including color filters. Each of the color filters may selectively transmit light of a specific wavelength (or specific color). In an embodiment, the color filter layer may be omitted.

A window may be provided on the light functional layer LFL to protect an exposed surface (or upper surface) of the display panel DP. The window may protect the display panel DP from an external impact. The window may be connected to the light functional layer LFL by an optically transparent adhesive (or bonding) agent. The window may have a multilayer structure selected from among a glass substrate, a plastic film, and a plastic substrate. The multilayer structure may be formed through a successive process or an adhesion process using an adhesive layer. The entirety or portion of the window may have flexibility.

FIG. 5 is a sectional view illustrating another embodiment of the display panel of FIG. 3.

Referring to FIG. 5, another embodiment of a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be substantially the same as the substrate SUB, the pixel circuit layer PCL, the display element layer DPL, and the light functional layer LFL described above with reference to FIG. 4. Hereinafter, any repetitive detailed description thereof will be omitted.

The input sensing layer ISL may sense a user input on an upper surface (or display surface) of the display panel DP′. The input sensing layer ISL may include components suitable for sensing an external object such as the hand of the user, a pen, or the like. In an embodiment, for example, the input sensing layer ISL may include touch electrodes.

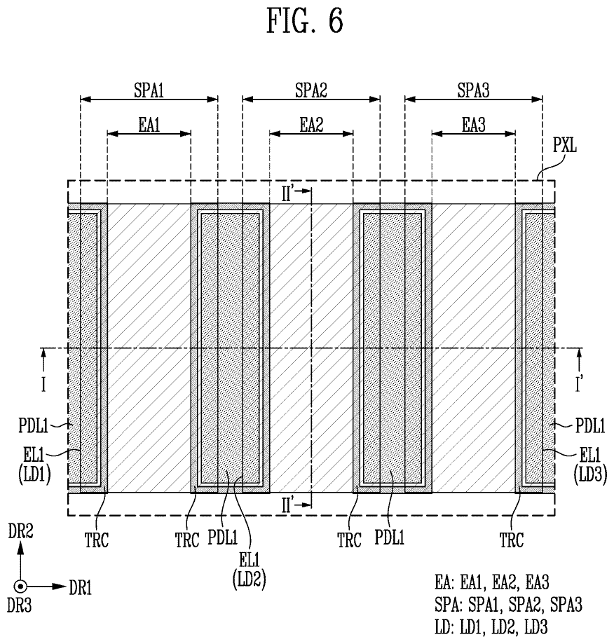

FIG. 6 is a plan view illustrating an embodiment of one of the pixels PXL of FIG. 3.

Referring to FIG. 6, in an embodiment, each of the pixels PXL may include a plurality of sub-pixels. In an embodiment, for example, the pixel PXL may include the first to third sub-pixels SP1 to SP3 of FIG. 3. The first to third sub-pixels SP1 to SP3 may be arranged in the first direction DR1. However, the arrangement of the pixel PXL is not limited thereto, and may be changed in various ways depending on the embodiments. In an embodiment, for example, the first to third sub-pixels SP1 to SP3 may be arranged in a zigzag pattern.

The first to third sub-pixels SP1 to SP3 may be respectively disposed in the first to third sub-pixel areas SPA1 to SPA3. In an embodiment, the first and third sub-pixel areas SPA1 to SPA3 may be arranged in the first direction DR1, and may be adjacent to each other in the first direction DR1. Furthermore, the first and third sub-pixel areas SPA1 to SPA3 may have substantially a same shape as each other. However, the shapes of the first to third sub-pixel areas SPA1 to SPA3 are not limit ed to the aforementioned example.

First electrodes EL1 may be respectively disposed in the first to third sub-pixel areas SPA1 to SPA3. The first electrodes EL1 may be arranged in the first direction DR1 and be spaced apart from each other.

The first electrode EL1 disposed in the first sub-pixel area SPA1 may be provided as (or define) the anode electrode AE (refer to FIG. 2) connected to the sub-pixel circuit SPC (refer to FIG. 2) of the first sub-pixel SP1. The first electrode EL1 disposed in the second sub-pixel area SPA2 may be provided as the anode electrode AE connected to the sub-pixel circuit SPC of the second sub-pixel SP2. The first electrode EL1 disposed in the third sub-pixel area SPA3 may be provided as the anode electrode AE connected to the sub-pixel circuit SPC of the third sub-pixel SP3.

First to third light emitting elements LD1 to LD3, each of which includes the first electrode EL1, may be respectively disposed in the first to third sub-pixel areas SPA1 to SPA3.

The first light emitting element LD1 may be provided as (or define) a light emitting element LD (refer to FIG. 2) connected to the sub-pixel circuit SPC (refer to FIG. 2) of the first sub-pixel SP1. The second light emitting element LD2 may be provided as a light emitting element LD connected to the sub-pixel circuit SPC of the second sub-pixel SP2. The third light emitting element LD3 may be provided as a light emitting element LD connected to the sub-pixel circuit SPC of the third sub-pixel SP3.

In an embodiment, for example, the first light emitting element LD1 may generate light in red color, the second light emitting element LD2 may generate light in green color, and the third light emitting element LD3 may generate light in blue color. However, the disclosure is not limited to the aforementioned example. In another embodiment, for example, all of the first to third light emitting elements LD1 to LD3 may generate light in blue color.

The first to third light emitting elements LD1 to LD3 may also be respectively disposed in the first to third sub-pixel areas SPA1 to SPA3. The first to third light emitting elements LD1 to LD3 may respectively overlap the first to third emission areas EA1 to EA3.

The first to third emission areas EA1 to EA3 may be areas that respectively overlap the first to third light emitting elements LD1 to LD3 to generate and emit light. The first to third emission areas EA1 to EA3 may respectively overlap the first to third sub-pixel areas SPA1 to SPA3, and may have surface areas less than those of the first to third sub-pixel areas SPA1 to SPA3, respectively.

In an embodiment, at least one trench TRC may be defined between each pair of the first to third emission areas EA1 to EA3. That is, one or more trenches TRC may be defined between each pair of emission areas adjacent to each other in the first direction DR1 among the first to third emission areas EA1 to EA3. In other words, the trenches TRC may be respectively defined on opposite sides of each of the sub-pixel areas SPA in a direction of the adjacent emission areas EA among the first to third emission areas EA1 to EA3. In an embodiment, the number of trenches TRC defined on opposite sides of each of the sub-pixel areas SPA may be one or more.

In an embodiment, for example, a single trench TRC overlapping the first and second emission areas EA1 and EA2 in the first direction DR1 may be defined between the first and second emission areas EA1 and EA2. A single trench TRC overlapping the second and third emission areas EA2 and EA3 in the first direction DR1 may be defined between the second and third emission areas EA2 and EA3. In such an embodiment, between the third emission area EA3 and the first emission area EA1 that are respectively included in adjacent pixels PXL, a single trench TRC overlapping the third emission area EA3 and the first emission area EA1 in the first direction DR1 may be defined.

In an embodiment, each of the trenches TRC may have a closed-loop shape in a plan view or when viewed in the third direction DR3. Hence, some portions of the first to third emission elements LD1 to LD3 that overlap the trenches TRC may be disconnected by the trenches TRC.

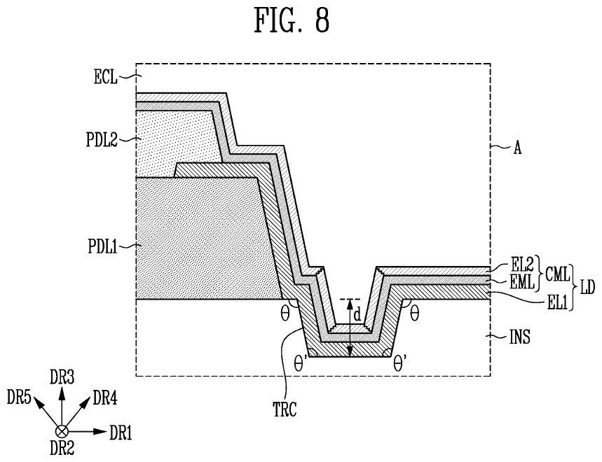

In an embodiment, a second electrode EL2 (refer to FIG. 8) included in each of the first to third light emitting elements LD1 to LD3 may be disconnected by the trench TRC. By a disconnected portion of the second electrode EL2 disposed inside the closed-loop shape of the trench TRC, a portion of the second electrode EL2 included in each of the first to third light emitting elements LD1 to LD3 may float (or be in a floating state) relative to a portion of the second electrode EL2 that is disposed outside the closed-loop shape of the trench TRC. In other words, the portion of the second electrode EL2 included in each of the first to third light emitting elements LD1 to LD3, which is disposed inside the closed-loop shape of the trench TRC, may float and be electrically isolated from surroundings thereof. The portion of the second electrode EL2 included in each of the first to third light emitting elements LD1 to LD3, which is disposed inside the closed-loop shape of the trench TRC, may be electrically insulated from the portion of the second electrode EL2 that is disposed outside the closed-loop shape of the trench TRC.

In such an embodiment, a portion of the second electrode EL2 included in each of the first to third light emitting elements LD1 to LD3, which overlaps the trench TRC, may be disconnected, such that the portion of the second electrode EL2 that is disposed inside the closed-loop shape of the trench TRC may float. Accordingly, a portion of each of the first to third light emitting elements LD1 to LD3 that overlaps the trench TRC or is disposed inside the closed-loop shape of the trench TRC may not emit light.

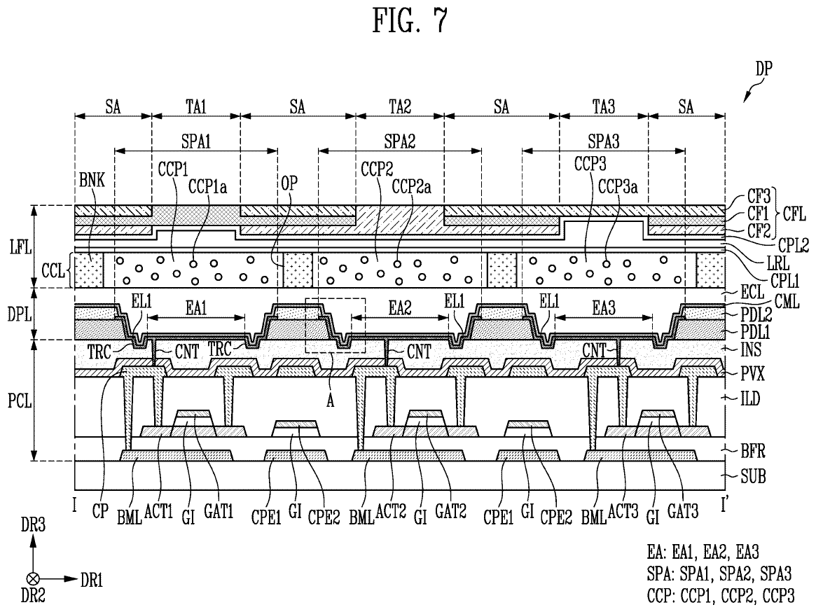

Hence, each of the trenches TRC may be adjacent to only a portion of each of the corresponding emission areas EA. In other words, the trenches TRC may not be connected to each other, and may be spaced apart from each other in the first direction DR1. Here, if the trenches TRC are connected to each other to enclose the entirety of each of the emission areas EA, the second electrode EL2 (refer to FIG. 7) overlapping the trenches TRC may be disconnected by the trenches TRC, resulting in floating not only the inside of each trench TRC but also the emission area EA. Hence, each of the trenches TRC may be adjacent to only a portion of each of the corresponding emission areas EA.

In an embodiment, the trenches TRC may define the first to third emission areas EA1 to EA3 that respectively overlap the first to third sub-pixel areas SPA1 to SPA3.

In other words, since the area where the trench TRC is defined may be an area that cannot emit light, the portions of the first to third light emitting elements LD1 to LD3 that are disposed outside the closed-loop shapes of the trenches TRC may be respectively defined as the first to third emission areas EA1 to EA3. Hence, each of the emission areas EA may be disposed between the corresponding adjacent trenches TRC. In other words, the trenches TRC and the emission areas EA may be alternately arranged in the first direction DR1.

In an embodiment, the sum of lengths of sides of each of the first to third emission areas EA1 to EA3 that are adjacent to the trenches TRC may be greater than the sum of sides that are not adjacent to the trenches TRC. In other words, in the case where each of the first to third sub-pixel areas SPA1 to SPA3 has a rectangular shape, each of the trenches TRC may be disposed adjacent to long sides of the corresponding rectangles rather than short sides.

First pixel defining layers PDL1 may be respectively disposed in areas between the first to third emission areas EA1 to EA3. In other words, the first pixel defining layers PDL1 may not overlap the first to third emission areas EA1 to EA3 in a plan view or in the third direction DR3.

Each of the first pixel defining layers PDL1 may be disposed inside the closed-loop shape of the corresponding trench TRC without overlapping the trench TRC. In other words, the trenches TRC, the emission areas EA, and the first pixel defining layers PDL1 may overlap each other in the first direction DR1, and portions of the trenches TRC (e.g., in the case where each of the trench TRC has a rectangular frame shape, portions corresponding to the long sides of the rectangular frame) may be disposed between the first pixel defining layers PDL1 and the emission areas EA.

The first electrodes EL1 may respectively overlap the first to third emission areas EA1 to EA3, and may partially overlap the corresponding trenches TRC. Here, a width of each of the first electrodes EL1 in the first direction DR1 may be greater than a width of each of the first to third emission areas EA1 to EA3 in the first direction DR1. Therefore, portions of each of the first electrodes EL1 that do not overlap the corresponding emission area EA may overlap the corresponding trenches TRC and the corresponding first pixel defining layers PDL1.

Each of the first pixel defining layers PDL1 may partially overlap an edge of each of the corresponding first electrodes EL1. The edge portion of the first electrode EL1 that overlaps the first pixel defining layer PDL may have an incline (or an inclined surface) on the first pixel defining layer PDL1. The portions of the first electrode EL1 that overlap the first pixel defining layers PDL1 are inside the corresponding trenches TRC, and therefore do not correspond to the emission areas EA, and can reflect light emitted from the emission areas EA through the inclines, thereby enhancing the light output efficiency of the display panel DP.

FIG. 7 is a sectional view taken along line I-I′ of FIG. 6.

Referring to FIG. 7, in an embodiment, the pixel circuit layer PCL may be disposed on the substrate SUB. The pixel circuit layer PCL may include bottom metal layers BML, first capacitor electrodes CPE1, a buffer layer BFR, first to third active electrodes ACT1 to ACT3, gate insulating layers GI, first to third gate electrodes GAT1 to GAT3, second capacitor electrodes CPE2, an interlayer dielectric ILD, connection electrodes CP, a passivation layer PVX, and an insulating layer INS.

The bottom metal layers BML and the first capacitor electrodes CPE1 may be disposed on the substrate SUB. The buffer layer BFR may be disposed on the substrate SUB and may cover the bottom metal layers BML and the first capacitor electrodes CPE1.

The first to third active electrodes ACT1 to ACT3 may be disposed on the buffer layer BFR. The gate insulating layers GI may be respectively disposed on the first to third active electrodes ACT1 to ACT3. Each of the gate insulating layers GI may have an island shape in a plan view or when viewed in the third direction DR3. The first gate electrode GAT1 may be disposed on the gate insulating layer GI provided on the first active electrode ACT1. The first active electrode ACT1 and the first gate electrode GAT1 may form a first transistor. The second gate electrode GAT2 may be disposed on the gate insulating layer GI provided on the second active electrode ACT2. The second active electrode ACT2 and the second gate electrode GAT2 may form a second transistor. The third gate electrode GAT3 may be disposed on the gate insulating layer GI provided on the third active electrode ACT3. The third active electrode ACT3 and the third gate electrode GAT3 may form a third transistor.

The gate insulating layers GI may also be disposed on the buffer layer BFR. The second capacitor electrodes CPE2 may be respectively disposed on the gate insulating layers GI provided on the buffer layer BFR. The second capacitor electrodes CPE2 may respectively overlap the first capacitor electrodes CPE1 in the third direction DR3, thereby forming capacitors.

The interlayer dielectric ILD may be disposed on the buffer layer BFR and may cover the first to third active electrodes ACT1 to ACT3, the second capacitor electrodes CPE2, the gate insulating layers GI, and the first to third gate electrodes GAT1 to GAT3.

The connection electrodes CP may be disposed on the interlayer dielectric ILD. The connection electrodes CP may be connected to the first to third active electrodes ACT1 to ACT3 and the bottom metal layers BML through constant holes defined in a layer therebelow, e.g., the interlayer dielectric ILD or the buffer layer BFR. The passivation layer PVX may be disposed on the interlayer dielectric ILD and may cover the connection electrodes CP. The passivation layer PVX may have a same (constant or uniform) thickness along the profiles of the connection electrodes CP.

The insulating layer INS may be disposed on the passivation layer PVX. The insulating layer INS may planarize an upper surface of the pixel circuit layer PCL. In an embodiment, the insulating layer INS may include organic material.

In an embodiment, the insulating layer INS may include at least one trench TRC and at least one contact hole CNT.

The trench TRC may be disposed adjacent to each of the first to third emission areas EA1 to EA3, and may be adjacent to a portion of each of the first to third emission areas EA1 to EA3 without overlapping the first to third emission areas EA1 to EA3. In the drawings, the trench TRC is illustrated as having a trapezoidal cross-sectional shape, but embodiments according to the disclosure are not limited thereto.

The contact hole CNT may be positioned in each of the first to third sub-pixel areas SPA1 to SPA3, and may be defined through the insulating layer INS and the passivation layer PVX.

The light-emitting-element layer DPL may be disposed on the insulating layer INS. The light-emitting-element layer DPL may include the first pixel defining layers PDL1, the first electrodes EL1, a second pixel defining layer PDL2, a common layer CML, and an encapsulation layer ECL. Although not illustrated, connection electrodes, passivation layer, and insulating layer may be further disposed between the insulating layer INS and the light-emitting-element layer DPL.

The first pixel defining layers PDL1 may be disposed on the insulating layer INS. The first pixel defining layers PDL1 may partially overlap corresponding perimeters of the first to third sub-pixel areas SPA1 to SPA3. In other words, the first pixel defining layers PDL1 may not overlap the first to third emission areas EA1 to EA3, and may be respectively disposed inside the trenches TRC without overlapping the trenches TRC in a plan view. Accordingly, portions of each of the trenches TRC may be positioned between the corresponding first pixel defining layer PDL1 and the corresponding emission areas EA.

The first pixel defining layer PDL1 may include organic material. In an embodiment, for example, the first pixel defining layer PDL1 may include polyimide (PI).

The first electrodes EL1 may be disposed on the insulating layer INS and the first pixel defining layers PDL1. The first electrodes EL1 may be respectively disposed in the first to third sub-pixel areas SPA1 to SPA3, and may be spaced apart from each other. Furthermore, the first electrodes EL1 may respectively overlap the first to third emission areas EA1 to EA3. The first electrodes EL1 may be respectively connected to the connection electrodes CP through the contact holes CNT. Therefore, the first electrodes EL1 may be respectively connected to the first to third transistors through the connection electrodes CP.

Each of the first electrodes EL1 may extend from the corresponding emission area EA to the corresponding first pixel defining layers PDL1. Accordingly, each of the first electrodes EL1 may partially overlap the trenches TRC defined on opposite sides of the emission area EA. The edge portions of each of the first electrodes EL1 may partially overlap the first pixel defining layers PDL1 disposed on the opposite sides of the emission area EA.

Here, each of the first electrodes EL1 may be disposed along the respective profiles of the corresponding trenches TRC and first pixel defining layers PDL1. In an embodiment, for example, each of the first electrodes EL1 may extend in a planar profile along the insulating layer INS in the emission area EA, may be bent several times along the trenches TRC, and may have a profile inclined along the first pixel defining layers PDL1. In other words, the respective portions of the first electrodes EL1 that overlap the first pixel defining layers PDL1 may be disposed on side surfaces of the first pixel defining layers PDL1, and may have inclined portions corresponding to those of the side surfaces of the first pixel defining layers PDL1.

In an embodiment, each of the first electrodes EL1 may have a structure in which indium tin oxide (ITO) and silver (Ag) are alternately stacked. Since each of the first electrodes EL1 includes indium tin oxide (ITO) and silver (Ag), the reflectivity of the first electrode EL1 may be improved.

The second pixel defining layer PDL2 may be disposed on the first pixel defining layers PDL1 and the first electrodes EL1. The second pixel defining layer PDL2 may overlap the first pixel defining layers PDL1 and cover the entireties of the respective edges of the first electrodes EL1.

The second pixel defining layer PDL2 may include organic material. However, the disclosure is not limited to the aforementioned example. In another embodiment, the second pixel defining layer PDL2 may further include light blocking material. The second pixel defining layer PDL2 may further include light blocking material such as a black pigment, a dye, or carbon black, in addition to the material constituting the first pixel defining layer PDL1.

The common layer CML may be disposed on the first electrodes EL1 and the second pixel defining layer PDL2. The common layer CML may overlap the entire areas of the first to third sub-pixel areas SPA1 to SPA3, and may extend across the entire display area DA of FIG. 3. Accordingly, the common layer CML may overlap the trenches TRC. Furthermore, the common layer CML may be disposed along the respective profiles of the first electrodes EL1 and the second pixel defining layer PDL2. In an embodiment, for example, the common layer CML may extend with multiple bends along each of the first electrodes EL1 and the second pixel defining layer PDL2.

The first electrode EL1 and the common layer CML that are disposed in the first emission area EA1 may form the first light emitting element LD1 of FIG. 6. The first electrode EL1 and the common layer CML that are disposed in the second emission area EA2 may form the second light emitting element LD2 of FIG. 6. The first electrode EL1 and the common layer CML that are disposed in the third emission area EA3 may form the third light emitting element LD3 of FIG. 6.

In an embodiment, the common layer CML may include an emission layer and a second electrode. Hereinafter, the structure of the common layer CML overlapping the trench TRC will be described in detail.

FIG. 8 is an enlarged sectional view illustrating area A of FIG. 7.

Referring to FIG. 8, in an embodiment, an emission layer EML may be disposed on the first electrodes EL1 and the second pixel defining layer PDL2. The emission layer EML may include an organic emission layer configured to generate light, an electron transport layer configured to transport electrons, and a hole transport layer configured to transport holes.

Here, a direction in which the emission layer EML emits light may include a fourth direction DR4 and a fifth direction DR5 rather than the third direction DR3. The fourth direction DR4 may be a direction that intersects with the first direction DR1 and the third direction DR3. The fifth direction DR5 may be a direction symmetrical to the fourth direction DR4 with respect to the third direction DR3. However, the disclosure is not limited to the aforementioned example.

The emission layer EML may overlap the entire areas of the first to third emission areas EA1 to EA3, and may extend across the entire display area DA of FIG. 3. Accordingly, the emission layer EML may overlap the trenches TRC. Furthermore, the emission layer EML may also be disposed along the respective profiles of the first electrodes EL1 and the first pixel defining layers PDL1. In an embodiment, for example, the emission layer EML may extend with multiple bends along each of the first electrodes EL1 and the first pixel defining layers PDL1.

The second electrode EL2 may be disposed on the emission layer EML. The second electrode EL2 may overlap the first to third sub-pixel areas SPA1 to SPA3, and may be provided as the cathode electrode CE of FIG. 2 in each of the first to third sub-pixels. Furthermore, the second electrode EL2 may be a thin-film metal layer having a thickness allowing light emitted from the emission layer EML to pass therethrough.

The second electrodes EL2 may overlap the first to third emission areas EA1 to EA3, and may be continuously connected across the entire display area DA. Accordingly, the second electrode EL2 may overlap the trenches TRC. In such an embodiment, the second electrode EL2 may be partially disconnected by the trenches TRC between the first to third emission areas EA1 to EA3.

The second electrode EL2 may be disposed along the profile of the emission layer EML. In an embodiment, for example, the second electrode EL2 may extend with multiple bends along the emission layer EML. In such an embodiment where the second electrode EL2 is bent, the second electrode EL2 may be cut off or cracked depending on the degree of bending described below, potentially causing a disconnection in the second electrode EL2. Here, the cause of disconnection in the second electrode EL2 is not limited to cases where the second electrode EL2 is cut off or cracked.

In an embodiment, an angle formed between inclined surfaces of the insulating layer INS that define the respective trenches TRC and an upper surface of the insulating layer INS (hereinafter referred to as an incline angle θ) may be greater than 0° and be less than or equal to approximately 130°.

In a case where the incline angle θ of the trench TRC is less than or equal to approximately 130°, the second electrode EL2 may be disconnected starting from a point where the incline of the trench TRC begins. In other words, when the second electrode EL2 is bent by the trench TRC, if a bending angle is approximately 130° or less, the second electrode EL2 may be disconnected. Furthermore, the second electrode EL2 may also be disconnected in a case where an incline angle θ′ between the inclined surface of the insulating layer INS2 that defines the trench TRC and a lower surface of the insulating layer INS is approximately 130° or less. Therefore, the portion of the second electrode EL2 that overlaps the trench TRC may be disconnected multiple times due to bent portions of the trench TRC.

In an embodiment, the incline angle θ of the trench TRC may be greater than 0° and less than or equal to approximately 145°, and a depth d of the trench TRC may be greater than approximately 1 micrometer.

In a case where the incline angle θ of the trench TRC is greater than 0° and less than or equal to approximately 145° and the depth d of the trench TRC is greater than approximately 1 micrometer, the second electrode EL2 may be disconnected. In other words, even when the incline angle θ of the trench TRC is relatively large, or in a range from more than approximately 130° to approximately 145°, the second electrode EL2 may be disconnected if the depth d of the trench TRC is greater than approximately 1 micrometer. Here, the portion of the second electrode EL2 that overlaps the trench TRC may be disconnected one or more times due to the trench TRC.

In an embodiment, as described above, the portion of the second electrode EL2 that overlaps the trench TRC and the portion of the second electrode EL2 that is disposed inside the closed-loop shape of the trench TRC may be insulated from the portion of the second electrode EL2 that is disposed outside the closed-loop shape of the trench TRC. Since the portion of the second electrode EL2 that overlaps the inside of the trench TR floats (or is in a floating state), the light emitting element LD that overlaps the inside of the trench TRC may not emit light. In other words, the emission area EA may be limited to the outside of the trench TRC. Accordingly, the surface area of the emission area EA that is the emission surface area of the light emitting element LD may be reduced.

In an embodiment, a portion of each of the first to third light emitting elements LD1 to LD3 that is disposed inside the closed-loop shape of the trench may have an incline due to the first pixel defining layer PDL1. Here, in a case where the inclined portion of each of the first to third light emitting elements LD1 to LD3 emits light, each of the first to third light emitting elements LD1 to LD3 emits light in the fourth direction DR4 and the fifth direction DR5, which may result in the loss of some light emitted from the inclined portion. Therefore, under conditions where the total amount of light is the same, the emission efficiency of each of the first to third light emitting elements LD1 to LD3 may be improved by limiting the emission surface area of each of the first to third light emitting elements LD1 to LD3 to the first to third emission areas EA1 to EA3 that are planarized portions, through the use of the trench TRC.

Here, the first electrode EL1 may extend in the first direction DR1 without being disconnected even in the case where the incline angle θ of the trench TRC is greater than approximately 0° and less than or equal to approximately 130°.

In an embodiment, the second electrode EL2 may be disconnected by the trenches TRC between the first to third emission areas EA1 to EA3. Accordingly, color mixing between sub-pixels caused by the overall extension of the second electrode EL2 may be effectively prevented, and leakage current between the sub-pixels may be effectively prevented.

Referring back to FIG. 7, the encapsulation layer ECL may be disposed on the common layer CML. The encapsulation layer ECL may include at least one inorganic encapsulation layer and at least one organic encapsulation layer. In an embodiment, the encapsulation layer ECL may include a first inorganic encapsulation layer disposed on the second electrode EL2, an organic encapsulation layer disposed on the first inorganic encapsulation layer, and a second inorganic encapsulation layer disposed on the organic encapsulation layer.

The light functional layer LFL may be disposed on the encapsulation layer ECL. The light functional layer LFL may include a color conversion layer CCL, a first capping layer CPL1, a low-refractive layer LRL, a second capping layer CPL2, and a color filter layer CFL.

The color conversion layer CCL may be disposed on the encapsulation layer ECL. The color conversion layer CCL may include color conversion patterns CCP and a bank layer BNK.

The bank layer BNK may define or be provided with openings OP that respectively correspond to the first to third sub-pixel areas SPA1 to SPA3. The openings OP may respectively overlap the first to third emission areas EA1 to EA3.

The bank layer BNK may include organic material. The bank layer BNK may include light blocking material. In an embodiment, for example, at least a portion of the bank layer BNK may include light blocking material such as a black pigment, a dye, or carbon black.

The color conversion patterns CCP may be respectively disposed in the openings OP of the bank layer BNK. In other words, the bank layer BNK may enclose the color conversion patterns CCP. The color conversion patterns CCP may respectively overlap the first to third emission areas EA1 to EA3 in the third direction DR3. The color conversion patterns CCP may include first to third color conversion patterns CCP1 to CCP3. The first to third color conversion patterns CCP1 to CCP3 may be spaced apart from each other.

In the first to third color conversion patterns CCP1 to CCP3 and the first to third emission areas EA1 to EA3 that respectively overlap each other, the surface areas of the first to third color conversion patterns CCP1 to CCP3 may be greater than those of the first to third emission areas EA1 to EA3, respectively. That is, in the first color conversion pattern CCP1 and the first emission area EA1 that overlap each other, the surface area of the first color conversion pattern CCP1 may be greater than that of the first emission area EA1. In the second color conversion pattern CCP2 and the second emission area EA2 that overlap each other, the surface area of the second color conversion pattern CCP2 may be greater than that of the second emission area EA2. In the third color conversion pattern CCP3 and the third emission area EA3 that overlap each other, the surface area of the third color conversion pattern CCP3 may be greater than that of the third emission area EA3. Since the surface area of the color conversion pattern CCP is greater than that of the overlapping emission area EA, a greater amount of light emitted from the emission area EA may be incident on the color conversion pattern CCP.

The first color conversion pattern CCP1 may overlap the first sub-pixel area SPA1 and the first emission area EA1. The first color conversion pattern CCP1 may convert light incident on the first color conversion pattern CCP1 to light in red color. In an embodiment, for example, the first color conversion pattern CCP1 may include a resin portion, a scatterer, and wavelength conversion particles CCP1a.

The wavelength conversion particles CCP1a may include quantum dots. The quantum dots may absorb the incident light and emit light having a wavelength different from that of the incident light. In an embodiment, for example, the wavelength conversion particles CCP1a of the first color conversion pattern CCP1 may include quantum dots that absorb the incident light and emit light in red color. Therefore, the first color conversion pattern CCP1 may convert the incident light to emit light in red color.

The second color conversion pattern CPP2 may overlap the second sub-pixel area SPA2 and the second emission area EA2. The second color conversion pattern CCP2 may convert light incident on the second color conversion pattern CCP2 to light in green color. In an embodiment, for example, the second color conversion pattern CCP2 may include a resin portion, a scatterer, and wavelength conversion particles CCP2a.

The wavelength conversion particles CCP2a may include quantum dots. The quantum dots may absorb the incident light and emit light having a wavelength different from that of the incident light. In an embodiment, for example, the wavelength conversion particles CCP2a of the second color conversion pattern CCP2 may include quantum dots that absorb the incident light and emit light in green color. Therefore, the second color conversion pattern CCP2 may convert the incident light to emit light in green color.

The third color conversion pattern CPP3 may overlap the third sub-pixel area SPA3 and the third emission area EA3. The third color conversion pattern CCP3 may convert light incident on the third color conversion pattern CCP3 to light in blue color. In an embodiment, for example, the third color conversion pattern CCP3 may include a resin portion, a scatterer, and wavelength conversion particles CCP3a.

The wavelength conversion particles CCP3a may include quantum dots. The quantum dots may absorb the incident light and emit light having a wavelength different from that of the incident light. In an embodiment, for example, the wavelength conversion particles CCP3a of the third color conversion pattern CCP3 may include quantum dots that absorb the incident light and emit light in blue color. Therefore, the third color conversion pattern CCP3 may convert the incident light to emit light in blue color.

However, the disclosure is not limited to the aforementioned example, and in the case where light incident on the third color conversion pattern CCP3 is light in blue color, the third color conversion pattern CCP3 may include only the resin portion and the scatterer, and may transmit the incident light.

The first capping layer CPL1 may be disposed on the color conversion layer CCL. The first capping layer CPL1 may cover an entire upper surface of the color conversion layer CCL. The first capping layer CPL1 may include inorganic material.

The low refractive layer LRL may be disposed on the first capping layer CPL1. The low refractive layer LRL may enhance light extraction efficiency, thus increasing the luminance of the display panel DP. The low refractive layer LRL may include organic material.

The second capping layer CPL2 may be disposed on the low refractive layer LRL. The second capping layer CPL2 may cover an entire lower surface of the color filter layer CFL. The second capping layer CPL2 may include inorganic material.

The color filter layer CFL may be disposed on the second capping layer CPL2. The color filter layer CFL may include first to third color filter patterns CF1, CF2, and CF3.

The first color filter pattern CF1 may overlap the first sub-pixel area SPA1 and the first emission area EA1 in the third direction DR3, and may selectively transmit light in red color. Here, the incident light that is not converted by the first color conversion pattern CCP1 may be blocked by the first color filter pattern CF1. Accordingly, in the first emission area EA1, light in red color may be emitted to the outside (i.e., in the third direction DR3).

The second color filter pattern CF2 may overlap the second sub-pixel area SPA2 and the second emission area EA2 in the third direction DR3, and may selectively transmit light in green color. Here, the incident light that is not converted by the second color conversion pattern CCP2 may be blocked by the second color filter pattern CF2. Accordingly, in the second emission area EA2, light in green color may be emitted to the outside.

The third color filter pattern CF3 may overlap the third sub-pixel area SPA3 and the third emission area EA3 in the third direction DR3, and may selectively transmit light in blue color. Here, the incident light that is not converted by the third color conversion pattern CCP3 may be blocked by the third color filter pattern CF3. Accordingly, in the third emission area EA3, light in blue color may be emitted to the outside.

The color filter layer CFL may include first to third transmitting areas TA1 to TA3 and a light blocking area SA. The first to third transmitting areas TA1 to TA3 may be areas where light passes through, and may respectively overlap the first to third emission areas EA1 to EA3. The light blocking area SA may be an area where light cannot pass through, and may enclose the first to third transmitting areas TA1 to TA3.

Each of the first color filter pattern CF1, the second color filter pattern F2, and the third color filter pattern CF3 may be disposed to further overlap the light blocking area SA. In other words, portions of the first to third color filter patterns CF1 to CF3 may overlap each other in the third direction DR3, thereby defining the light blocking area SA.

In an embodiment, for example, the first color filter pattern CF1 may overlap the first transmitting area TA1 and the light blocking area SA, and may not overlap the second and third transmitting areas TA2 and TA3 in the third direction DR3. The second color filter pattern CF2 may overlap the second transmitting area TA2 and the light blocking area SA, and may not overlap the first and third transmitting areas TA1 and TA3 in the third direction DR3. The third color filter pattern CF3 may overlap the third transmitting area TA3 and the light blocking area SA, and may not overlap the first and second transmitting areas TA1 and TA2 in the third direction DR3. Accordingly, color mixing between the adjacent first to third emission areas EA1 to EA3 may be effectively prevented.

In an embodiment, the trenches TRC may overlap only the light blocking area SA without overlapping the first to third transmitting areas TA1 to TA3 in the third direction DR3. Hence, the surface areas of the first to third transmitting areas TA1 to TA3 on a plane may be less than or equal to the surface areas of the first to third emission areas EA1 to EA3 on the plane.

In an embodiment, due to the trench TRC defined between the emission areas EA, the second electrode EL2 may be disconnected in a portion overlapping the trench TRC, and the portion of the second electrode EL2 that is disposed inside the trench TRC may float, thereby limiting the emission area EA of the light emitting element LD to the outside of the trench TRC. Furthermore, the first electrode EL1 may be disposed to overlap the first pixel defining layer PDL1 disposed inside the trench TRC. Accordingly, the first electrode EL1 overlapping the inside of the trench TRC may have an incline formed by the side surface of the first pixel defining layer PDL1. In other words, since the portion of the light emitting element LD that has an incline due to the first pixel defining layer PDL1 does not emit light, the loss of light emitted from the light emitting element LD due to the incline may be minimized. Furthermore, since the first electrode EL1 has an inline, the first electrode EL1 may reflect light that is emitted from the color conversion layer CCL and is incident on a rear surface of the display panel DP rather than a front surface thereof, thereby emitting the light through the front surface. Consequently, the light output efficiency of the display device may be improved.

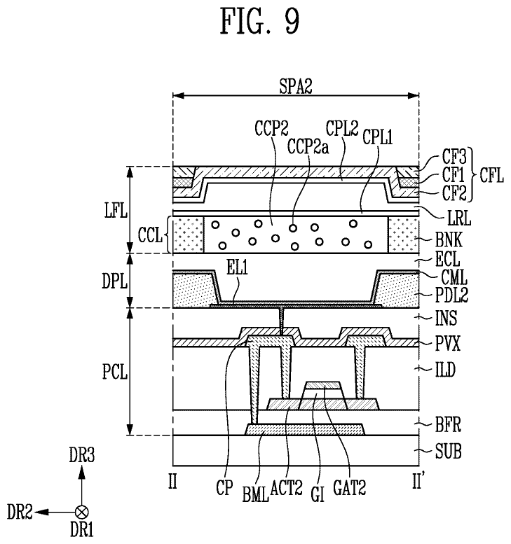

FIG. 9 is a sectional view taken along line II-II′ of FIG. 6.

Referring to FIGS. 6 and 9, the trenches TRC defined in the insulating layer INS may overlap the first to third emission areas EA1 to EA3 and the first electrodes EL1 only in the first direction DR1, and may not overlap the first to third emission areas EA1 to EA3 in the second direction DR2. In other words, the trenches TRC may enclose sides of each of the first to third emission areas EA1 to EA3 only in the first direction DR1, and may not enclose the sides of each of the first to third emission areas EA1 to EA3 in the third direction DR2. In other words, the trenches TRC may be arranged only in a direction in which the first to third emission areas EA1 to EA3 are adjacent to each other (e.g., in the first direction DR1).

Therefore, the second electrode EL2 that is disposed on the insulating layer INS and overlaps the trenches TRC may be disconnected only in the first direction DR1 with respect to the first to third emission areas EA1 to EA3 without being disconnected in the second direction DR2. Accordingly, the second electrode EL2 may be electrically connected in the entire display area.

Furthermore, the first pixel defining layers PDL1 (refer to FIG. 7) disposed on the insulating layer INS may overlap the first to third emission areas EA1 to EA3 and the first electrodes EL1 only in the first direction DR1, and may not overlap the first to third emission areas EA1 to EA3 in the second direction DR2. In other words, the first pixel defining layers PDL1 may enclose the sides of each of the first to third emission areas EA1 to EA3 only in the first direction DR1, and may not enclose the sides of each of the first to third emission areas EA1 to EA3 in the third direction DR2. In other words, the first pixel defining layers may also be arranged only in the direction in which the first to third emission areas EA1 to EA3 are adjacent to each other (e.g., in the first direction DR1), similar to the arrangement of the trenches TRC.

The second pixel defining layer PDL2 may enclose the entireties of the first to third emission areas EA1 to EA3, and may cover the entireties of the edges of the first electrodes EL1. In other words, the second pixel defining layer PDL2 may overlap the first to third emission areas EA1 to EA3 and the first electrodes EL1 even in the second direction DR2.

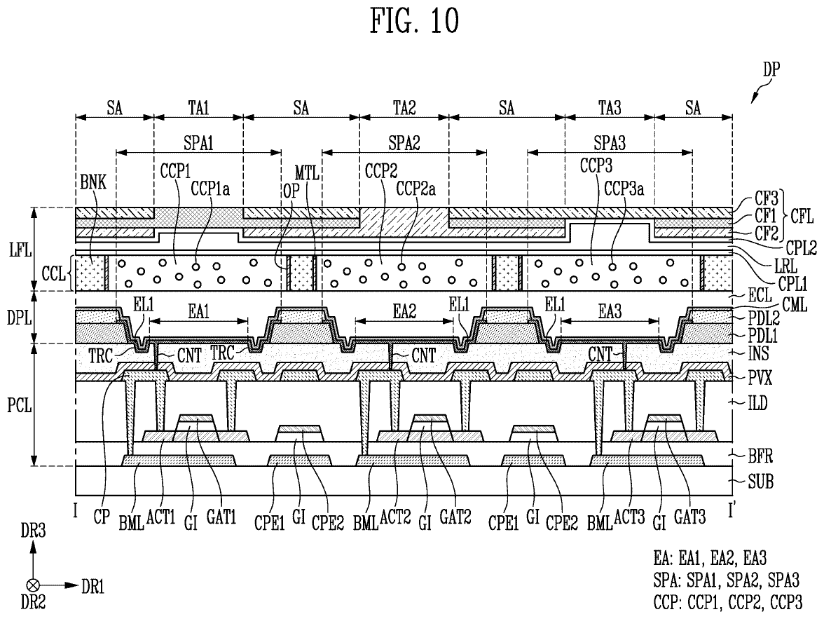

FIG. 10 is a sectional view illustrating another embodiment of FIG. 7.

A display panel DP' shown in FIG. 10 is substantially the same as the aforementioned embodiment except that the bank layer BNK further includes a metal layer MTL. Accordingly, any repetitive detailed description of the same or like elements as those described above will be omitted or simplified.

Referring to FIG. 10, the bank layer BNK may further include the metal layer MTL on a surface thereof. In an embodiment, for example, the metal layer MTL may be further disposed on a side surface of the bank layer BNK that defines the openings OP. In other words, the metal layer MTL may be disposed on the side surface of the bank layer BNK that contacts the color conversion patterns CCP. Here, the metal layer MTL may include at least one selected from indium tin oxide (ITO) and aluminum (AI). The bank layer BNK further includes the metal layer MTL and is therefore capable of reflecting light incident in the direction toward the bank layer BNK on the surface of the metal layer MTL, thereby improving the light emission efficiency of the display panel DP′.

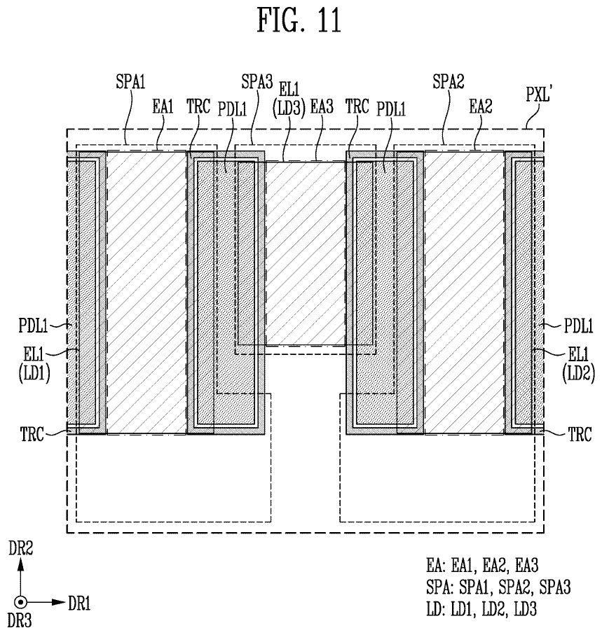

FIG. 11 is a plan view illustrating another embodiment of one of the pixels of FIG. 3. Hereinafter, for convenience of description, any repetitive detailed description of the same or like elements as those described above will be omitted or simplified.

Referring to FIG. 11, a pixel PXL′ may include a plurality of sub-pixels. In an embodiment, for example, the pixel PXL′ may include the first to third sub-pixels SP1 to SP3 of FIG. 3. The first to third sub-pixels SP1 to SP3 may be arranged in the first direction DR1.

The first to third sub-pixels SP1 to SP3 may be respectively disposed in the first to third sub-pixel areas SPA1 to SPA3. In an embodiment, the first sub-pixel area SPA1 and the second sub-pixel area SPA2 may have shapes that are symmetrical with respect to the second direction DR2. Furthermore, the third sub-pixel area SPA3 may be disposed between the first and second sub-pixel areas SPA1 and SPA2, and may have a surface area smaller than the first and the second sub-pixel areas SPA1 and SPA2.

First electrodes EL1 may be respectively disposed in the first to third sub-pixel areas SPA1 to SPA3. The first electrodes EL1 may be arranged in the first direction DR1 and be spaced apart from each other.

First to third light emitting elements LD1 to LD3 that respectively include the first electrodes EL1 may be respectively disposed in the first to third sub-pixel areas SPA1 to SPA3.

The first to third emission areas EA1 to EA3 may be areas that respectively overlap the first to third light emitting elements LD1 to LD3 to generate and emit light. The first to third emission areas EA1 to EA3 may respectively overlap the first to third sub-pixel areas SPA1 to SPA3, and may have surface areas less than those of the first to third sub-pixel areas SPA1 to SPA3, respectively.

In an embodiment, at least one trench TRC may be defined between each pair of the first to third emission areas EA1 to EA3. That is, one or more trenches TRC may be defined between each pair of emission areas adjacent to each other in the first direction DR1 among the first to third emission areas EA1 to EA3. In other words, the trenches TRC may be respectively defined on opposite sides of each of the sub-pixel areas SPA in a direction of the adjacent emission areas EA among the first to third emission areas EA1 to EA3. Here, the number of trenches TRC defined on opposite sides of each of the sub-pixel areas SPA may be one or more.

In an embodiment, for example, a single trench TRC overlapping the first and third emission areas EA1 and EA3 in the first direction DR1 may be defined between the first and third emission areas EA1 and EA3. A single trench TRC overlapping the third and second emission areas EA3 and EA2 in the first direction DR1 may be defined between the third and second emission areas EA3 and EA2. In such an embodiment, between the second emission area EA2 and the first emission area EA1 that are respectively included in adjacent pixels PXL′, a single trench TRC overlapping the second emission area EA2 and the first emission area EA1 in the first direction DR1 may be defined.

In an embodiment, each of the trenches TRC may have a closed-loop shape. Accordingly, a second electrode EL2 (refer to FIG. 8) included in each of the first to third light emitting elements LD1 to LD3 may be disconnected by the trench TRC. By a disconnected portion of the second electrode EL2 disposed inside the closed-loop shape of the trench TRC, a portion of the second electrode EL2 included in each of the first to third light emitting elements LD1 to LD3 may float relative to a portion of the second electrode EL2 that is disposed outside the closed-loop shape of the trench TRC.

In other words, a portion of the second electrode EL2 included in each of the first to third light emitting elements LD1 to LD3, which overlaps the trench TRC, may be disconnected, such that the portion of the second electrode EL2 that is disposed inside the closed-loop shape of the trench TRC may float. Accordingly, a portion of each of the first to third light emitting elements LD1 to LD3 that overlaps the trench TRC or is disposed inside the closed-loop shape of the trench TRC may not emit light.

Furthermore, the trenches TRC may not be connected to each other, and may be spaced apart from each other in the first direction DR1.

First pixel defining layers PDL1 may be respectively disposed in areas between the first to third emission areas EA1 to EA3. Each of the first pixel defining layers PDL1 may be disposed inside the closed-loop shape of the corresponding trench TRC without overlapping the trench TRC.

The first electrodes EL1 may respectively overlap the first to third emission areas EA1 to EA3, and may partially overlap the corresponding trenches TRC. Here, a width of each of the first electrodes EL1 in the first direction DR1 may be greater than a width of each of the first to third emission areas EA1 to EA3 in the first direction DR1. Therefore, portions of each of the first electrodes EL1 that do not overlap the corresponding emission area EA may overlap the corresponding trenches TRC and the corresponding first pixel defining layers PDL1.

Each of the first pixel defining layers PDL1 may partially overlap an edge of each of the corresponding first electrodes EL1. The edge of the first electrode EL1 that overlaps the first pixel defining layer PDL may have an incline on the first pixel defining layer PDL1. The portions of the first electrode EL1 that overlap the first pixel defining layers PDL1 are inside the corresponding trenches TRC, and therefore do not correspond to the emission areas EA, and can reflect light emitted from the emission areas EA through the inclines, thereby enhancing the light output efficiency of the display panel DP.

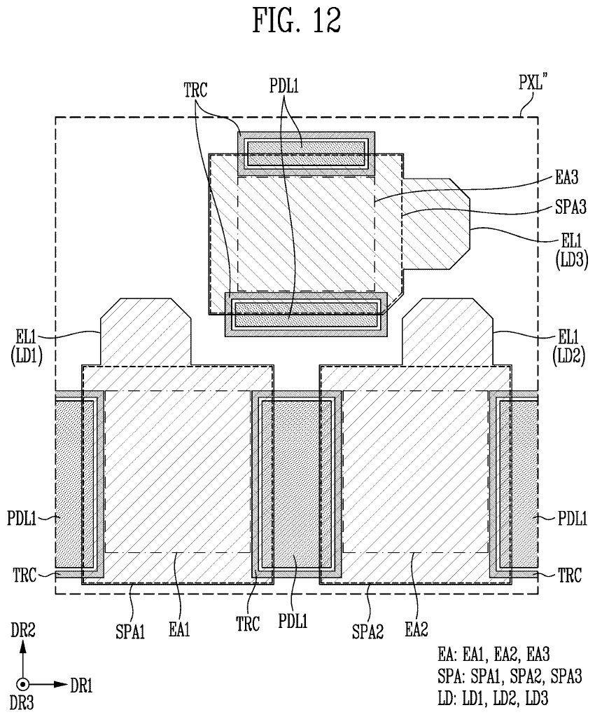

FIG. 12 is a plan view illustrating another embodiment of one of the pixels of FIG. 3. Hereinafter, for convenience of description, any repetitive detailed description of the same or like elements as those described above will be omitted or simplified.

Referring to FIG. 12, a pixel PXL″ may include a plurality of sub-pixels. In an embodiment, for example, the pixel PXL″ may include the first to third sub-pixels SP1 to SP3 of FIG. 3. The first to third sub-pixels SP1 to SP3 may be arranged in a zigzag pattern.

The first to third sub-pixels SP1 to SP3 may be respectively disposed in the first to third sub-pixel areas SPA1 to SPA3. Accordingly, the first to third sub-pixel areas SPA1 to SPA3 may be arranged in a zigzag pattern. In an embodiment, the first and second sub-pixel areas SPA1 and SPA2 may be arranged in the first direction DR1. The first sub-pixel area SPA1 and the second sub-pixel areas SPA2 may have shapes that are symmetrical with respect to the second direction DR2. Furthermore, the third sub-pixel area SPA3 may be spaced apart from the first and second sub-pixel areas SPA1 and SPA2 in the second direction DR2 between the first and second sub-pixel areas SPA1 and SPA2, and may have a surface area smaller than the first and the second sub-pixel areas SPA1 and SPA2.

In an embodiment, at least one trench TRC may be defined between each pair of the first to third emission areas EA1 to EA3. The trenches TRC may be respectively defined on opposite sides of each of the sub-pixel areas SPA in a direction of the adjacent emission areas EA among the first to third emission areas EA1 to EA3. Here, the number of trenches TRC defined on opposite sides of each of the sub-pixel areas SPA may be one or greater.

In an embodiment, for example, since the first and second emission areas EA1 and EA2 overlap each other in the first direction DR1, a single trench TRC overlapping the first and second emission areas EA1 and EA2 in the first direction DR1 may be defined between the first and second emission areas EA1 and EA2. Furthermore, between the second emission area EA2 and the first emission area EA1 that are respectively included in adjacent pixels PXL″, a single trench TRC overlapping the second emission area EA2 and the first emission area EA1 in the first direction DR1 may be defined. Since the third emission area EA3 overlaps the first and second emission areas EA1 and EA2 in the second direction DR2, a single trench TRC may be defined on each of opposite sides of the third emission area EA3 in the second direction DR2.

In an embodiment, each of the trenches TRC may have a closed-loop shape. Accordingly, a second electrode EL2 (refer to FIG. 8) included in each of the first to third light emitting elements LD1 to LD3 may be disconnected by the trench TRC. By a disconnected portion of the second electrode EL2 disposed inside the closed-loop shape of the trench TRC, a portion of the second electrode EL2 included in each of the first to third light emitting elements LD1 to LD3 may float relative to a portion of the second electrode EL2 that is disposed outside the closed-loop shape of the trench TRC.

In other words, a portion of the second electrode EL2 included in each of the first to third light emitting elements LD1 to LD3, which overlaps the trench TRC, may be disconnected, such that the portion of the second electrode EL2 that is disposed inside the closed-loop shape of the trench TRC may float. Accordingly, a portion of each of the first to third light emitting elements LD1 to LD3 that overlaps the trench TRC or is disposed inside the closed-loop shape of the trench TRC may not emit light.

First pixel defining layers PDL1 may be respectively disposed in areas between the first to third emission areas EA1 to EA3. Each of the first pixel defining layers PDL1 may be disposed inside the closed-loop shape of the corresponding trench TRC without overlapping the trench TRC.

The first electrodes EL1 may respectively overlap the first to third emission areas EA1 to EA3, and may partially overlap the corresponding trenches TRC. Portions of each of the first electrodes EL1 that do not overlap the corresponding emission area EA may overlap the corresponding trenches TRC and the corresponding first pixel defining layers PDL1.

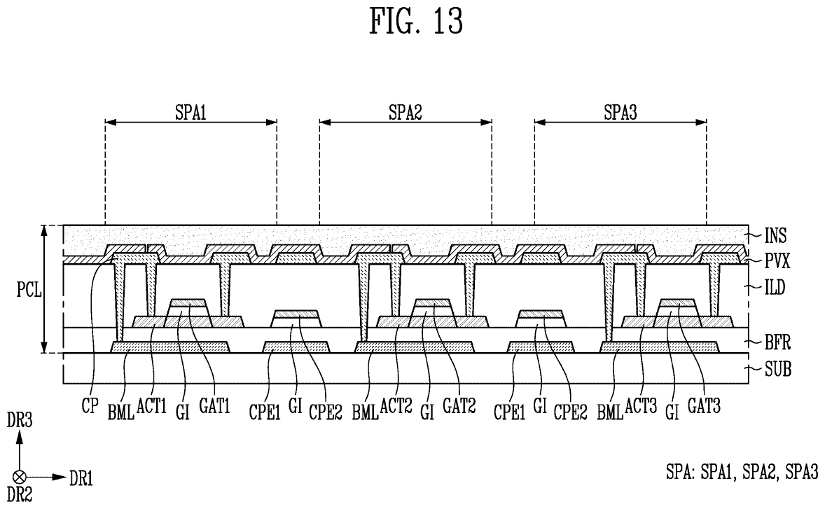

FIGS. 13 to 20 are diagrams illustrating a method of fabricating a display device in accordance with an embodiment of the disclosure.

FIGS. 13 to 20 illustrate an embodiment of a method of fabricating the display panel described with reference to FIGS. 1 to 9. Hereinafter, for convenience of description, any repetitive detailed description of the same or like elements as those described above will be omitted or simplified.

Referring to FIG. 13, the pixel circuit layer PCL may be formed on the substrate SUB. In an embodiment, the bottom metal layers BML and the first capacitor electrodes CPE1 may be formed on the substrate SUB. The buffer layer BFR may be formed on the substrate SUB to cover the bottom metal layers BML and the first capacitor electrodes CPE1.

The first to third active electrodes ACT1 to ACT3 may be formed on the buffer layer BFR. The gate insulating layer GI may be formed on each of the first to third active electrodes ACT1 to ACT3. Here, the gate insulating layer GI may be formed in an island shape. The first to third gate electrodes GAT1 to GAT3 may be respectively formed on the gate insulating layers GI provided on the first to the third active electrodes ACT1 to ACT3. The first active electrode ACT1 and the first gate electrode GAT1 may form a first transistor. The second active electrode ACT2 and the second gate electrode GAT2 may form a second transistor. The third active electrode ACT3 and the third gate electrode GAT3 may form a third transistor.

The gate insulating layers GI may also be formed on the buffer layer BFR. The second capacitor electrodes CPE2 may be respectively formed on the gate insulating layers GI provided on the buffer layer BFR. The second capacitor electrodes CPE2 may respectively overlap the first capacitor electrodes CPE1, thereby forming capacitors.

The interlayer dielectric ILD may be formed on the buffer layer BFR to cover the first to third active electrodes ACT1 to ACT3, the second capacitor electrodes CPE2, the gate insulating layers GI, and the first to third gate electrodes GAT1 to GAT3.

The connection electrodes CP may be formed on the interlayer dielectric ILD. The connection electrodes CP may be connected to the first to third active electrodes ACT1 to ACT3 and the bottom metal layers BML below through contact holes formed in the interlayer dielectric ILD. The passivation layer PVX may be formed on the interlayer dielectric ILD to cover the connection electrodes CP. Furthermore, contact holes for contact may be formed in the passivation layer PVX.

The insulating layer INS may be formed on the passivation layer PVX. The insulating layer INS may include or be formed of organic material.

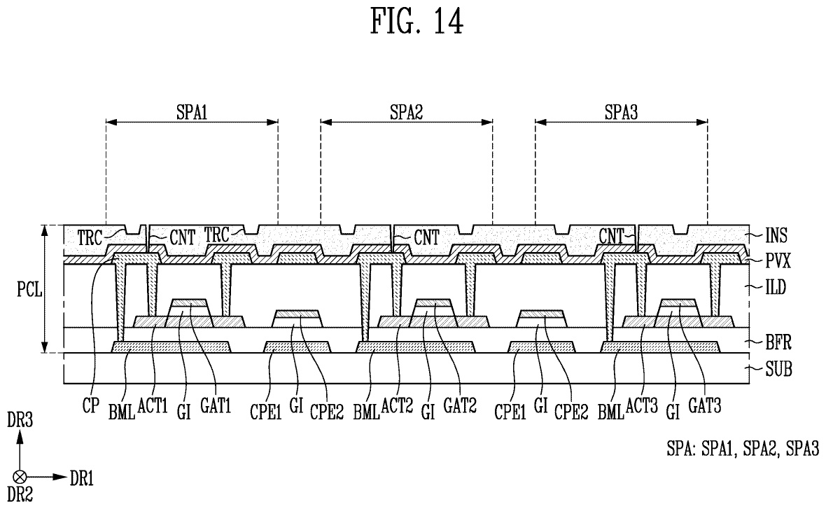

Referring to FIG. 14, the trenches TRC and the contact holes CNT may be formed in the insulating layer INS.

In an embodiment, the trenches TRC adjacent to portions of the first to third emission areas EA1 to EA3 may be formed in the insulating layer INS. The trenches TRC may be formed between the first to third emission areas EA1 to EA3 without overlapping the first to third emission areas EA1 to EA3. In such an embodiment, each of the trenches TRC may be formed in a closed-loop shape.

In an embodiment, each of the trenches TRC may be formed in a way such that an angle formed between the upper surface of the insulating layer INS and the inclined surface of the insulating layer INS that defines the trench TRC, i.e., the incline angle θ (refer to FIG. 8) of the trench TRC, is greater than 0° and less than or equal to approximately 130°.

The contact holes CNT that respectively overlap the first to third emission areas EA1 to EA3 may be formed in the insulating layer INS. The contact holes CNT may be formed through the insulating layer INS and the passivation layer PVX, thus exposing the respective connection electrodes CP.

In an embodiment, the contact holes CNT may be formed simultaneously with the trenches TRC. The depth of each of the contact holes CNT may be greater than that of each of the trenches TRC. Therefore, the trenches TRC and the contact holes CNT may be simultaneously formed using a halftone mask.

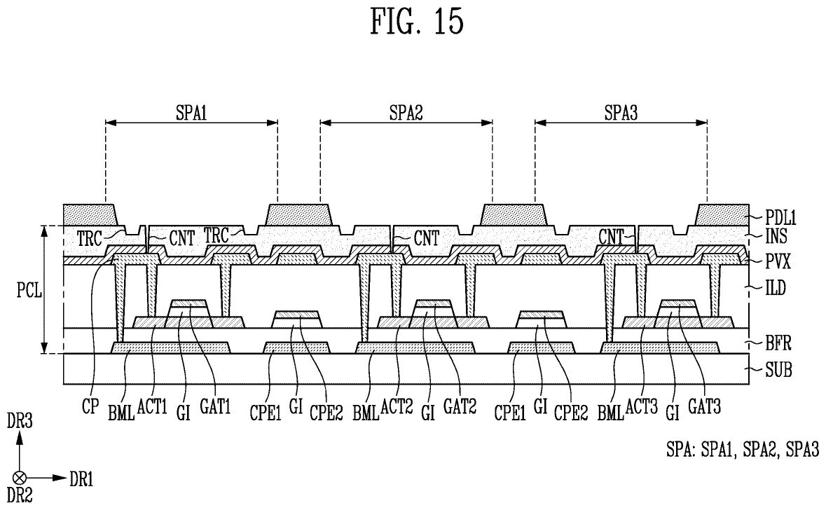

Referring to FIG. 15, the first pixel defining layers PDL1 may be formed on the insulating layer INS. The first pixel defining layers PDL1 may be respectively formed inside the closed-loop shapes of the trenches TRC without overlapping the trenches TRC. In other words, the first pixel defining layers PDL1 may also be formed between the first to third emission areas EA1 to EA3 without overlapping the first to third emission areas EA1 to EA3.

The first pixel defining layer PDL1 may include or be formed of organic material. In an embodiment, for example, the first pixel defining layer PDL1 may include or be formed of polyimide (PI).

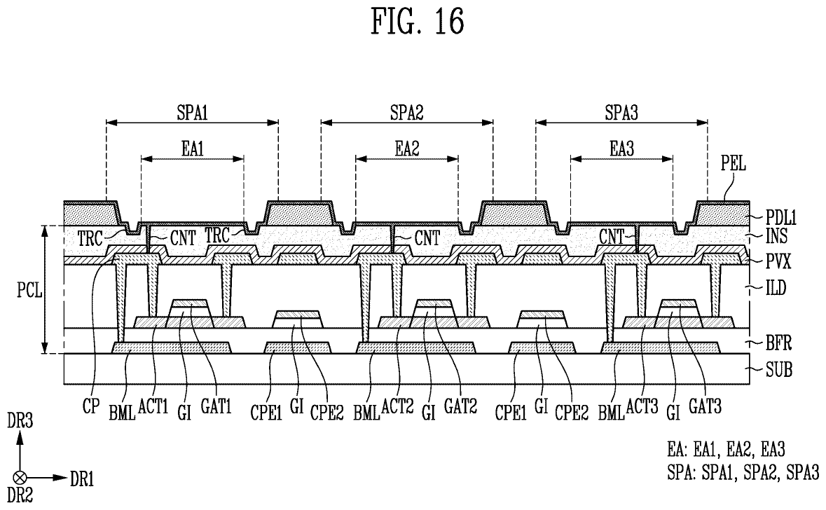

Referring to FIG. 16, a preliminary electrode layer PEL may be formed on the insulating layer INS and the first pixel defining layers PDL1. The preliminary electrode layer PEL may be formed to extend over the entire areas of the insulating layer INS and the first pixel defining layers PLD1. Therefore, the preliminary electrode layer PEL may be formed to bend along the respective profiles of the trenches TRC and the first pixel defining layers PLD1.

In an embodiment, the preliminary electrode layer PEL may be formed with a structure in which indium tin oxide (ITO) and silver (Ag) are alternately stacked.

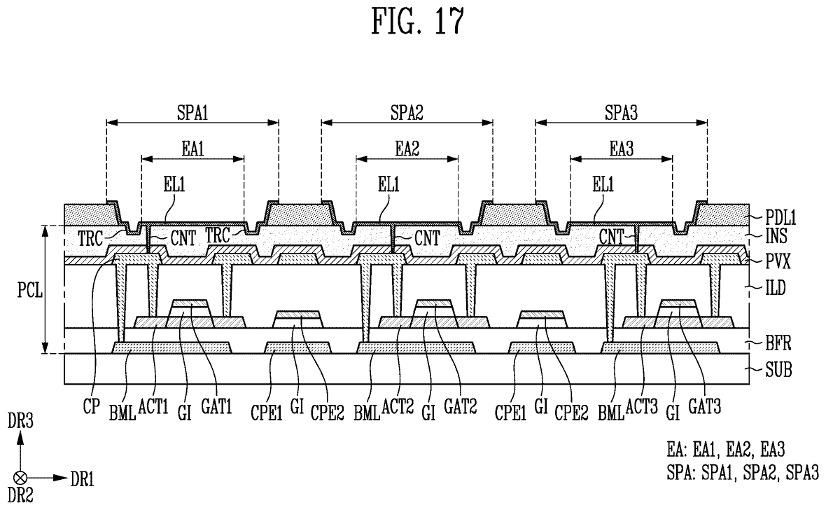

Referring to FIG. 17, the first electrodes EL1 may be formed by patterning the preliminary electrode layer PEL. The first electrodes EL1 may be etched to respectively overlap the first to third emission areas EA1 to EA3 and to be spaced apart from each other. Furthermore, the first electrodes EL1 may be formed to overlap portions of the trenches TRC. In addition, portions of the edges of each of the first electrodes EL1 may be formed to overlap the corresponding first pixel defining layers PDL1.

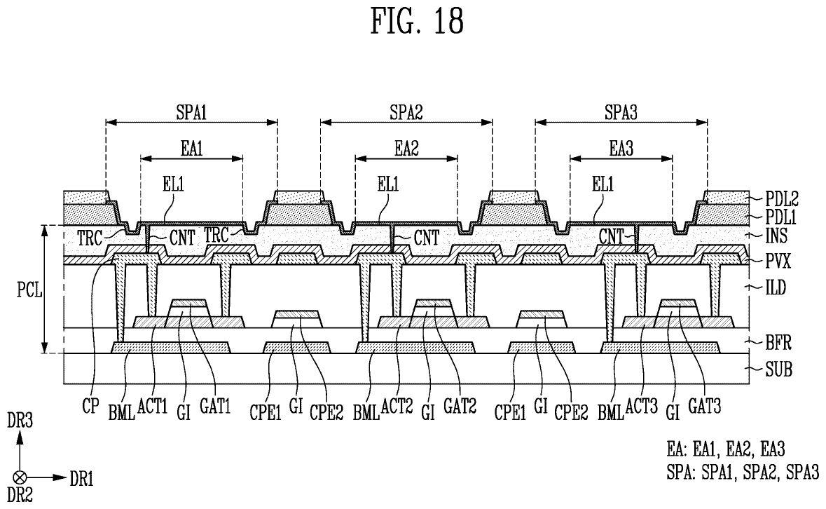

Referring to FIG. 18, the second pixel defining layer PDL2 may be formed on the first pixel defining layers PDL1 and the first electrodes EL1. The second pixel defining layer PDL2 may enclose the entireties of the first to third emission areas EA1 to EA3 without overlapping the first to third emission areas EA1 to EA3. Furthermore, the second pixel defining layer PDL2 may cover the entireties of the edges of the first electrodes EL1.

The second pixel defining layer PDL2 may include or be formed of organic material. However, the disclosure is not limited to the aforementioned example. In another embodiment, the second pixel defining layer PDL2 may further include light blocking material. The second pixel defining layer PDL2 may further include light blocking material such as a black pigment, a dye, or carbon black, in addition to the material constituting the first pixel defining layer PDL1.

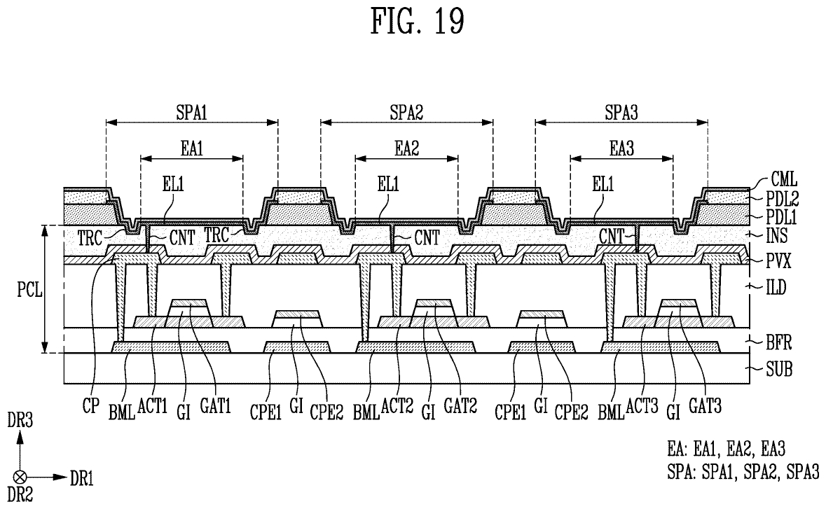

Referring to FIG. 19, the common layer CML may be formed on the entire areas of the first electrodes EL1 and the second pixel defining layer PDL2.

In an embodiment, the emission layer EML may be deposited on the entire areas of the first electrodes EL1 and the second pixel defining layer PDL2. Furthermore, the second electrode EL2 may be deposited on the entire area of the emission layer EML. Accordingly, each of the emission layer EML and the second electrode EL2 may overlap the entireties of the trenches TRC. Since the incline angle θ (refer to FIG. 8) of the trenches TRC is approximately 130° or less, the second electrode EL2 may be cut off or cracked by the inclines of the trenches TRC. Accordingly, the second electrode EL2 may be disconnected by the trenches TRC.

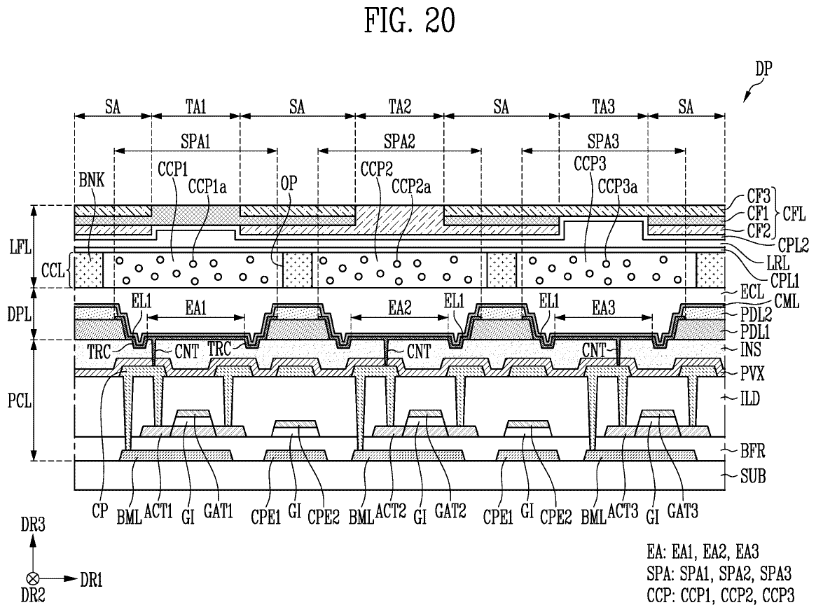

Referring to FIG. 20, the encapsulation layer ECL may be formed on the common layer CML. The light functional layer LFL may be formed on the encapsulation layer ECL.

In an embodiment, the color conversion layer CCL including the first to third color conversion patterns CCP1 to CCP3 and the bank layer BNK may be formed on the encapsulation layer ECL. The first capping layer CPL1 may be formed on the color conversion layer CCL. The low refractive layer LRL may be formed on the first capping layer CPL1. The second capping layer CPL2 may be formed on the low refractive layer LRL. The color filter layer CFL including the first to third color filter patterns CF1, CF2, and CF3 may be formed on the second capping layer CPL2. As a result, the display panel DP including the substrate SUB, the pixel circuit layer PCL, the display element layer DPL, and the light functional layer LFL may be formed.

In an embodiment, when the contact holes CNT are formed in the insulating layer INS, the trenches TRC may also be formed simultaneously, thereby simplifying an associated process without performing any additional processes.

A display device according to an embodiment is applicable to various types of electronic devices. In an embodiment, an electronic device includes the above-described display device and may further include other modules or devices having additional functions in addition to the display device.

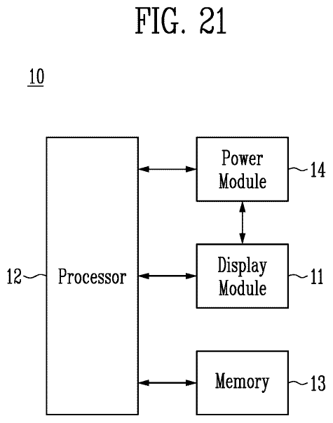

FIG. 21 is a block diagram of an electronic device according to an embodiment. Referring to FIG. 21, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

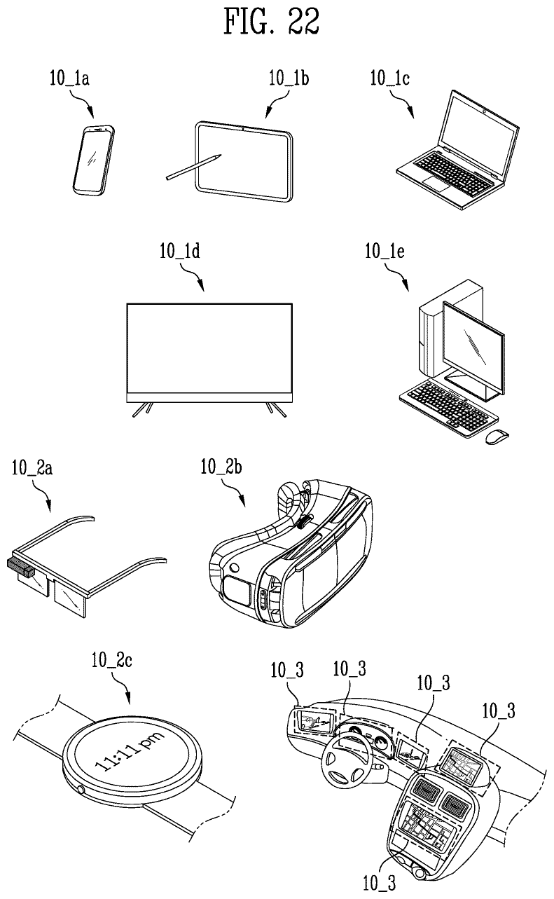

FIG. 22 shows schematic views of various embodiments of an electronic device.

Referring to FIG. 22, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

In embodiments of the disclosure, as described above, due to a trench defined between emission areas, a second electrode may be disconnected on a portion thereof overlapping the trench, and a portion of the second electrode that is disposed inside the trench may float, thereby limiting an emission area of a light emitting element to the outside of the trench. Accordingly, a portion of a light emitting element that has an incline due to a first pixel defining layer may not emit light, such that the loss of light emitted from the light emitting element due to the incline may be minimized.

In embodiments of the disclosure, since a first electrode has an incline, the first electrode may reflect light that is emitted from a color conversion layer and is incident on a rear surface of a display panel rather than a front surface thereof, thereby emitting the light through the front surface. Accordingly, the light output efficiency of the display device may be improved.

The effects of the disclosure are not limited by the foregoing, and other various effects are anticipated herein.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device, comprising:
a substrate;
an insulating layer disposed on the substrate, and including a trench defined in a portion thereof adjacent to an emission area without overlapping the emission area in a plan view;
a first electrode disposed on the insulating layer, and overlapping the emission area and partially overlapping the trench in the plan view;
an emission layer disposed on the first electrode, and overlapping the trench in the plan view; and
a second electrode disposed on the emission layer, and overlapping the trench in the plan view, and disconnected by the trench.

2. The display device according to claim 1, wherein the trench has a closed-loop shape in the plan view.

3. The display device according to claim 2, wherein a portion of the second electrode disposed inside the closed-loop shape of the trench is electrically disconnected from a portion of the second electrode disposed outside the closed-loop shape of the trench.

4. The display device according to claim 2, further comprising a first pixel defining layer disposed between the insulating layer and the first electrode without overlapping the emission area in the plan view.

5. The display device according to claim 4, wherein the first pixel defining layer is disposed inside the closed-loop shape of the trench without overlapping the trench in the plan view.

6. The display device according to claim 4, wherein a portion of the trench is defined between the first pixel defining layer and the emission area in the plan view.

7. The display device according to claim 4,
wherein the first pixel defining layer partially overlaps an edge of the first electrode in the plan view, and
wherein a portion of the first electrode which overlaps the first pixel defining layer in the plan view is disposed on a side surface of the first pixel defining layer, and has an incline corresponding to an incline of a side surface of the first pixel defining layer.

8. The display device according to claim 4, further comprising a second pixel defining layer disposed between the first electrode and the emission layer, and overlapping the first pixel defining layer in the plan view, and covering an edge of the first electrode.

9. The display device according to claim 2, wherein an angle formed between an upper surface of the insulating layer and an inclined surface of the insulating layer which defines the trench is in a range from 0° to about 130°.

10. The display device according to claim 2, further comprising a color filter layer disposed on the second electrode, and including a transmitting area overlapping the emission area in the plan view and a light blocking area enclosing the transmitting area in the plan view.

11. The display device according to claim 10, wherein the trench overlaps only the light blocking area without overlapping the transmitting area in the plan view.

12. The display device according to claim 1, further comprising a color conversion layer disposed on the second electrode, and including a color conversion pattern overlapping the emission area in the plan view and a bank layer enclosing the color conversion pattern in the plan view.

13. The display device according to claim 12, wherein a surface area of the color conversion pattern is greater than a surface area of the emission area.

14. The display device according to claim 12, wherein the bank layer includes a metal layer disposed on a side surface thereof which contacts the color conversion pattern.

15. A display device, comprising:
a substrate;
an insulating layer disposed on the substrate, and including trenches respectively defined between emission areas adjacent to each other in a first direction;
pixel defining layers disposed on the insulating layer, and respectively disposed inside the trenches without overlapping the emission areas in a plan view;
first electrodes disposed on the insulating layer and the pixel defining layers, and respectively overlapping the emission areas, and respectively partially overlapping the trenches in the plan view;
an emission layer disposed on the first electrodes, and overlapping entire portions of the emission areas in the plan view; and
a second electrode disposed on the emission layer, and overlapping the emission areas in the plan view, and disconnected by the trenches between the emission areas.

16. The display device according to claim 15,
wherein each of the trenches has a closed-loop shape in the plan view, and
wherein the pixel defining layers are respectively disposed inside the closed-loop shapes of the trenches.

17. The display device according to claim 15, wherein the trenches, the emission areas, and the pixel defining layers overlap each other in the first direction.

18. The display device according to claim 17,
wherein a width of each of the first electrodes in the first direction is greater than a width of each of the emission areas in the first direction, and
wherein a portion of each of the first electrodes, which does not overlap the emission area, overlaps the trenches and the pixel defining layers in the plan view.

19. The display device according to claim 15, wherein a sum of lengths of sides of each of the emission areas which are adjacent to the trenches is greater than a sum of lengths of sides thereof which are not adjacent to the trenches.

20. An electronic device, comprising:
a processor to provide input image data; and
a display device to display an image based on the input image data,
wherein the display device comprises: a substrate;
an insulating layer disposed on the substrate, and including a trench defined in a portion thereof adjacent to an emission area without overlapping the emission area in a plan view;
a first electrode disposed on the insulating layer, and overlapping the emission area and partially overlapping the trench in the plan view;
an emission layer disposed on the first electrode, and overlapping the trench in the plan view; and
a second electrode disposed on the emission layer, and overlapping the trench in the plan view, and disconnected by the trench.
